(19) United States
(12) Patent Application Publication
(10) Pub. No.: US 2026/0079392 A1
(43) Pub. Date: Mar. 19, 2026

(54) TEMPLATE AND METHOD OF MANUFACTURING TEMPLATE

(71) Applicant: Kioxia Corporation, Tokyo (JP)

(72) Inventors: Anupam MITRA, Yokkaichi Mie (JP); Masanori HIROSE, Mie Mie (JP); Yukichi KAMITA, Yokkaichi Mie (JP)

(73) Assignee: Kioxia Corporation, Tokyo (JP)

(21) Appl. No.: 19/072,183

(22) Filed: Mar. 6, 2025

(30) Foreign Application Priority Data
Sep. 17, 2024 (JP) 2024-159720

(51) Int. Cl. G03F 7/00; B29C 33/30; B29C 33/38; B29C 33/40; B29C 33/42; B29C 43/36; B29L 31/34; G03F 9/00

(52) U.S. Cl. CPC G03F 7/0002; B29C 33/30; B29C 33/3842; B29C 33/40; B29C 33/424; B29C 43/36; G03F 9/7042; G03F 9/7084; B29L 2031/34

(57) ABSTRACT

A template according to an embodiment includes a substrate, and a resin layer that is bonded to the substrate and has a pattern on a first surface opposite surface to a second surface facing a substrate, in which the resin layer and the substrate have opposed surfaces including a recess and a protrusion that are configured to be fitted to each other.

### CROSS-REFERENCE TO RELATED APPLICATIONS

This application is based upon and claims the benefit of priority from Japanese Patent Application No. 2024-159720, filed on Sep. 17, 2024; the entire contents of which are incorporated herein by reference.

### FIELD

Embodiments described herein relate generally to a template and a method of manufacturing a template.

### BACKGROUND

A manufacturing process for a semiconductor device may include an imprinting process. In the imprinting process, a template for transferring a pattern onto a semiconductor substrate is repeatedly used. To reproduce the template repeatedly used and worn out, the template may include a pattern portion formed of a replaceable resin layer, in some cases.

### BRIEF DESCRIPTION OF THE DRAWINGS

FIGS. 1A to 1F are schematic diagrams each illustrating an exemplary configuration of a template according to a first embodiment;

FIGS. 2A to 2D are cross-sectional views partially illustrating a procedure of an imprinting method using the template according to the first embodiment;

FIGS. 3A and 3B are cross-sectional views partially illustrating a procedure of a method of forming a pattern onto a semiconductor substrate according to the first embodiment;

FIGS. 4A and 4B are cross-sectional views sequentially illustrating parts of a procedure of a method of manufacturing a template mold according to the first embodiment;

FIGS. 5A to 5D are cross-sectional views sequentially illustrating parts of the procedure of the method of manufacturing the template mold according to the first embodiment;

FIGS. 6A to 6C are cross-sectional views sequentially illustrating parts of a procedure of a method of manufacturing the template according to the first embodiment;

FIGS. 7A to 7C are cross-sectional views sequentially illustrating parts of the procedure of the method of manufacturing the template according to the first embodiment;

FIG. 8 is a cross-sectional view partially illustrating a procedure of a method of reproducing the template according to the first embodiment;

FIGS. 9A and 9B are schematic diagrams illustrating an exemplary configuration of a template according to a first modification of the first embodiment;

FIGS. 10A and 10B are schematic diagrams illustrating an exemplary configuration of a template according to a second modification of the first embodiment;

FIG. 11 is a cross-sectional view partially illustrating a procedure of an imprinting method using the template according to the second modification of the first embodiment;

FIG. 12 is a cross-sectional view illustrating an exemplary configuration of a template mold used for manufacturing the template according to the second modification of the first embodiment;

FIGS. 13A and 13B are cross-sectional views sequentially illustrating parts of a procedure of a method of manufacturing the template according to the second modification of the first embodiment;

FIGS. 14A to 14C are cross-sectional views sequentially illustrating parts of the procedure of the method of manufacturing the template according to the second modification of the first embodiment;

FIG. 15 is a cross-sectional view sequentially illustrating parts of the procedure of the method of manufacturing the template according to the second modification of the first embodiment;

FIGS. 16A and 16B are schematic diagrams illustrating an exemplary configuration of a template according to a third modification of the first embodiment;

FIG. 17 is a cross-sectional view illustrating an exemplary configuration of a template mold used for manufacturing the template according to the third modification of the first embodiment;

FIGS. 18A to 18C are cross-sectional views sequentially illustrating parts of a procedure of a method of manufacturing the template according to the third modification of the first embodiment;

FIGS. 19A to 19C are cross-sectional views sequentially illustrating parts of the procedure of the method of manufacturing the template according to the third modification of the first embodiment;

FIGS. 20A to 20C are schematic diagrams each illustrating an exemplary configuration of a template according to another modification of the first embodiment;

FIGS. 21A to 21D are cross-sectional views sequentially illustrating parts of a procedure of a method of manufacturing a template mold according to a second embodiment;

FIGS. 22A to 22D are cross-sectional views sequentially illustrating parts of the procedure of the method of manufacturing the template mold according to the second embodiment;

FIGS. 23A to 23C are cross-sectional views sequentially illustrating parts of a procedure of a method of manufacturing the template according to the second embodiment;

FIGS. 24A to 24G are cross-sectional views sequentially illustrating parts of a procedure of a method of manufacturing a template mold according to a modification of the second embodiment; and

FIGS. 25A to 25G are cross-sectional views sequentially illustrating parts of a procedure of a method of manufacturing another template mold according to a modification of the second embodiment.

### DETAILED DESCRIPTION

A template according to an embodiment includes a substrate, and a resin layer that is bonded to the substrate and has a pattern on a first surface opposite surface to a second surface facing a substrate, in which the resin layer and the substrate have opposed surfaces with a recess and a protrusion that are configured to be fitted to each other.

Embodiments of the present invention will be described in detail below with reference to the drawings. Note that the present invention is not limited to the following embodiments. Furthermore, component elements in the following embodiments include component elements that are readily conceivable by a person skilled in the art or that are substantially equivalent.

### First Embodiment

Hereinafter, a first embodiment will be described in detail with reference to the drawings.

### (Configuration Example of Template)

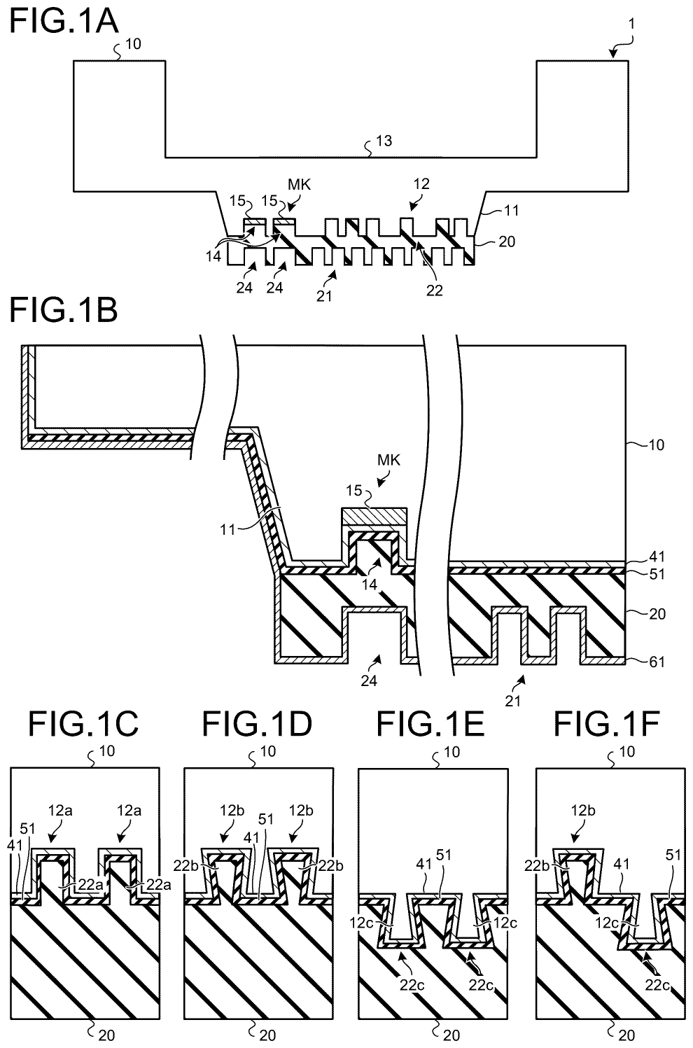

FIGS. 1A to 1F are schematic diagrams each illustrating an exemplary configuration of a template 1 according to a first embodiment. More specifically, FIG. 1A is a cross-sectional view illustrating the entire template 1, FIG. 1B is a partially enlarged cross-sectional view of the template 1, and FIGS. 1C to 1F are enlarged cross-sectional views of anchor patterns 12a to 12c and 22a to 22c included in the template 1.

The template 1 of the first embodiment is used for an imprinting process and includes a replaceable resin layer 20. In the imprinting process, a pattern 21 of the template 1 is pressed against and transferred to a resist layer formed on a semiconductor substrate. The resist layer onto which the pattern 21 is transferred is used as a mask to process the semiconductor substrate or the like, and therefore, enabling a desired pattern serving as a part of the semiconductor device to be formed on the semiconductor substrate.

As illustrated in FIG. 1A, the template 1 includes a quartz substrate 10 and the resin layer 20.

The quartz substrate 10 is formed in a flat plate shape, and has one surface including a mesa portion 11 protruding from the one surface. The quartz substrate 10 has the other surface including a recess called, for example, a counterbore 13 thereon.

The mesa portion 11 has a protruding surface where an anchor pattern 12 including a plurality of recesses and protrusions and an alignment mark MK are provided.

The alignment mark MK includes a recess 14 recessed relative to a surface of the mesa portion 11, and a metal layer 15, such as a chromium layer, provided on a bottom surface of the recess 14. The alignment mark MK is used to align the semiconductor substrate and the template 1 when the template 1 is pressed against the resist layer of the semiconductor substrate.

Note that the mesa portion 11 is also provided with an alignment mark and an inspection mark which are not illustrated, in addition to the alignment mark MK. The alignment mark and the inspection mark which are not illustrated may have various shapes such as a line-and-space pattern, a dot pattern, and a hole pattern. These alignment mark and inspection mark may or may not include a metal layer such as a chromium layer.

The resin layer 20 is at least one of a silicon-containing resin layer, an acrylic resin layer, or a urethane resin layer, and is bonded to the protruding surface of the mesa portion 11. Hereinafter, surfaces where the resin layer 20 and the mesa portion 11 are bonded to each other are also referred to as a bonding surface of the resin layer 20, a bonding surface of the mesa portion 11, or the like. In other words, the protruding surface of the mesa portion 11 protruding from the quartz substrate 10 corresponds to the bonding surface of the mesa portion 11.

The resin layer 20 has an anchor pattern 22 including a plurality of recesses and protrusions configured to be fitted to the anchor pattern 12 of the mesa portion 11, on the bonding surface to the mesa portion 11. Fitting the anchor pattern 12 of the mesa portion 11 and the anchor pattern 22 of the resin layer 20 to each other and bonding the mesa portion 11 and the resin layer 20 to each other enables to increase adhesive strength against lateral misalignment between the mesa portion 11 and the resin layer 20. In other words, the anchor patterns 12 and 22 of the mesa portion 11 and the resin layer 20 have an anchor effect to secure the mesa portion 11 and the resin layer 20 to each other. A force applied to the mesa portion 11 and the resin layer 20 due to the lateral misalignment between the mesa portion 11 and the resin layer 20 is also referred to as lateral stress.

Note that the anchor patterns 12 and 22 may be dispersedly provided on the entire bonding surfaces of the resin layer 20 and the mesa portion 11, or may be provided partially on the bonding surfaces. In addition, instead of or in addition to the anchor patterns 12 and 22, the alignment mark MK which is described above, the other anchor mark, inspection mark, or the like which is not illustrated, may be functioned as an anchor pattern.

In addition, the resin layer 20 has a surface opposite to the bonding surface to the mesa portion 11 where the pattern 21 for transferring to the resist layer of the semiconductor substrate is provided. The pattern 21 may have various shapes such as a line-and-space pattern, a dot pattern, and a hole pattern, according to a processed shape of the semiconductor substrate or the like.

In addition, the resin layer 20 includes, in the surface where the pattern 21 is formed, a recess 24 vertically overlapping the alignment mark MK of the quartz substrate 10.

As illustrated in FIG. 1B, the template 1 includes a plurality of layers such as protective layers 41 and 61 and an adhesive layer 51, on an interface between the resin layer 20 and the quartz substrate 10, a surface of the resin layer 20, and the like.

The protective layer 41 is arranged on the surface of the quartz substrate 10 where the mesa portion 11 is provided and a side surface of the quartz substrate 10. In other words, the protective layer 41 continuously covers the surface of the quartz substrate 10 on a side on which the mesa portion 11 is provided, each of the side surfaces of the mesa portion 11, and the protruding surface of the mesa portion 11, that is, the bonding surface to the resin layer 20, from the side surface of the quartz substrate 10.

In the recess 14 of the alignment mark MK, the protective layer 41 covers side surfaces of the recess 14 and the metal layer 15 arranged in the recess 14.

The protective layer 41 is, for example, at least one of an aluminum oxide layer, a titanium oxide layer, or a silicon oxide layer, and is a layer for protecting a surface of the quartz substrate 10.

The adhesive layer 51 is arranged on the surface of the quartz substrate 10 where the mesa portion 11 is provided, via the protective layer 41. In other words, the adhesive layer 51 continuously covers the surface of the quartz substrate 10 on the side on which the mesa portion 11 is provided, each side surface of the mesa portion 11, and the protruding surface of the mesa portion 11, that is, the bonding surface to the resin layer 20, via the protective layer 41. However, the adhesive layer 51 is not provided on the side surface of the quartz substrate 10.

In the recess 14 of the alignment mark MK, the adhesive layer 51 covers the side surfaces of the recess 14 and a surface of the metal layer 15 provided on the bottom surface of the recess 14, via the protective layer 41.

The adhesive layer 51 is, for example, a spin-on carbon (SOC) layer or the like, and is a layer for bonding the mesa portion 11 of the quartz substrate 10 and the resin layer 20. The SOC layer is a layer that is formed using spin coating or the like and contains a large amount of carbon.

The protective layer 61 is arranged on a surface of the quartz substrate 10 where the mesa portion 11 is provided but other than the mesa portion 11, and a side surface of the quartz substrate 10, and a side surface of the resin layer 20 and the surface thereof where the pattern 21 is provided. In other words, the protective layer 61 reaches from the side surface of the quartz substrate 10, the surface of the quartz substrate 10 on the side on which the mesa portion 11 is provided, and the side surface of the mesa portion 11, to the side surface of the resin layer 20, and continuously covers up to the pattern 21 of the resin layer 20.

On the side surface of the quartz substrate 10, the protective layer 61 is arranged via the above-described protective layer 41. On the surface of the quartz substrate 10 on the side on which the mesa portion 11 is provided and on the side surface of the mesa portion 11, the protective layer 61 is arranged via the protective layer 41 and the adhesive layer 51 which are described above. The protective layer 61 directly covers the surface of the resin layer 20, that is, on the side surface of the resin layer 20 and the surface provided with the pattern 21.

On the surface of the resin layer 20 where the pattern 21 is provided, the protective layer 61 covers side surfaces and a bottom surface of the above-described recess 24 provided at a position where the recess 24 vertically overlaps the alignment mark MK, and covers the entire pattern 21 in conformity with recesses and protrusions of the pattern 21.

The protective layer 61 is, for example, a silicon oxide layer or the like, and is a layer for protecting the pattern 21 of the resin layer 20 from being worn.

As illustrated in FIGS. 1C to 1F, the anchor pattern 22 of the resin layer 20 and the anchor pattern 12 of the mesa portion 11 of the quartz substrate 10 which are configured to be fitted to each other are allowed to have various shapes.

In the example of FIG. 1C, the anchor pattern 12a of recessed shape having substantially vertical side surfaces is provided in the quartz substrate 10, and the anchor pattern 22a of protruding shape to fit to the anchor pattern 12a is provided on the resin layer 20.

As in the example of FIG. 1D, the anchor patterns 12 and 22 may have a tapered shape. In other words, the anchor pattern 12b in the quartz substrate 10 is allowed to have a tapered shape that narrows from a bottom surface of the anchor pattern 12b of recessed shape toward an open end in the surface of the quartz substrate 10. In contrast, the anchor pattern 22b of protruding shape on the resin layer 20 is allowed to have a tapered shape that narrows from an upper surface of the anchor pattern 22b, toward a base portion on the surface of the resin layer 20.

This configuration makes it possible to fit the anchor pattern 12b in the quartz substrate 10 and the anchor pattern 22b on the resin layer 20 to each other. In addition, combining the anchor pattern 12b in the quartz substrate 10 and the anchor pattern 22b on the resin layer 20 in a wedged manner makes it possible to increase the adhesive strength between the mesa portion 11 and the resin layer 20 against the lateral stress.

As in the example of FIG. 1E, the recesses and protrusions of the anchor patterns 12 and 22 may be reversed between the quartz substrate 10 side and the resin layer 20 side. In other words, the anchor pattern 12c of protruding shape may be provided on the quartz substrate 10, and an anchor pattern 22c of recessed shape to which the anchor pattern 12c on the quartz substrate 10 is allowed to be fitted may be provided in the resin layer 20. The anchor patterns 12c and 22c may have tapered shapes that face in directions opposite to each other as illustrated in FIG. 1E, or may have shapes that have substantially vertical side surfaces as illustrated in FIG. 1A.

As in the example of FIG. 1F, the recesses and protrusions may be mixed in the anchor patterns 12 and 22 in the quartz substrate 10 and the resin layer 20. In other words, the anchor pattern 12b of recessed shape and the anchor pattern 12c of protruding shape are provided in the quartz substrate 10, and the anchor pattern 22b of protruding shape and the anchor pattern 22c of recessed shape that are allowed to be respectively fitted to the anchor patterns 12b and 12c in the quartz substrate 10 are provided in the resin layer 20. The anchor patterns 12c and 22b and the anchor patterns 12b and 22c may have tapered shapes that face in directions opposite to each other as illustrated in FIG. 1F, or may have shapes that have substantially vertical side surfaces as illustrated in FIG. 1A.

Note that, as described above, the anchor patterns 12 and 22 illustrated in FIGS. 1C to 1F are merely examples, and the anchor patterns 12 and 22 may have various shapes and combinations other than those illustrated above. For example, the anchor patterns 12 and 22 may not have a regular pattern as described above. As an example, the anchor patterns 12 and 22 may be formed by roughening at least one of the bonding surface of the mesa portion 11 or the bonding surface of the resin layer 20. In this configuration, the roughened bonding surface of the mesa portion 11 or the resin layer 20 has recesses and protrusions of irregular shape.

### (Method of Forming Pattern)

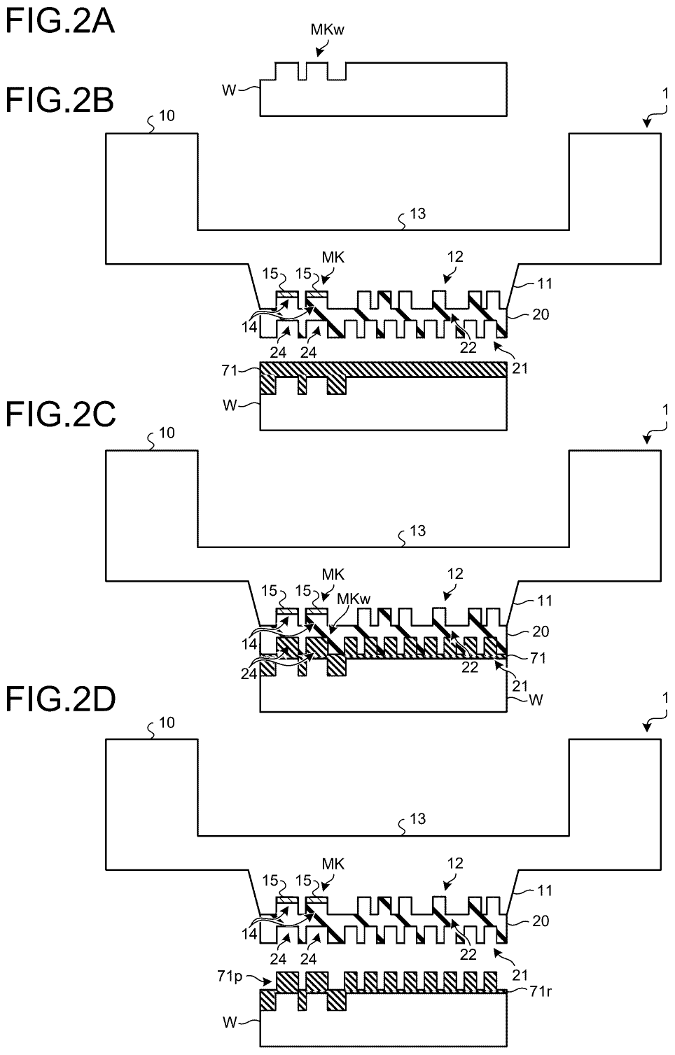

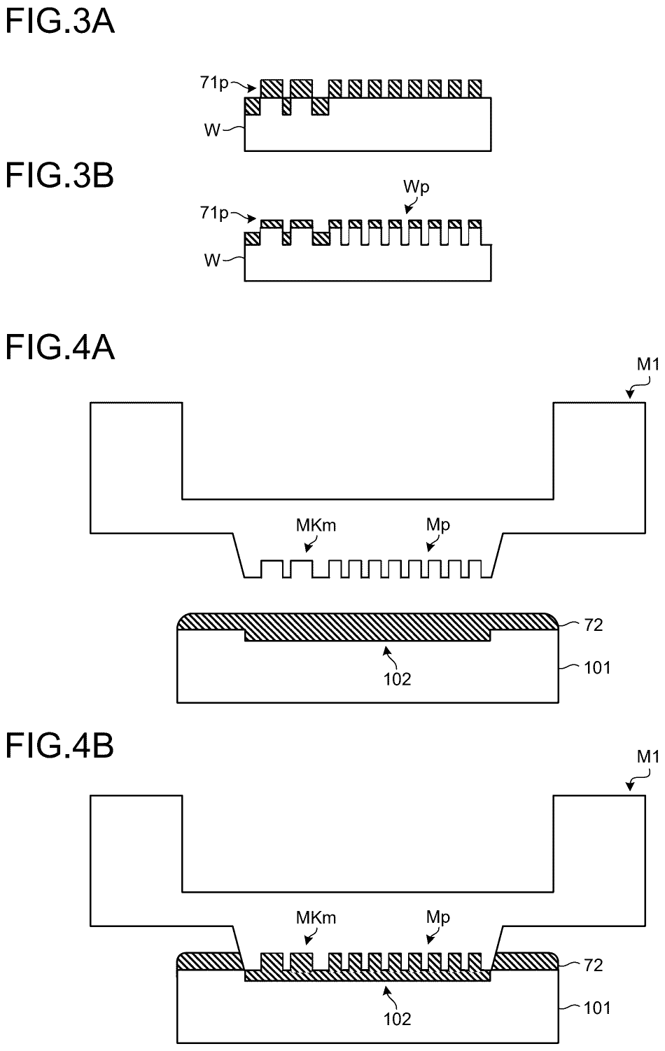

Next, a method of forming a pattern on a semiconductor substrate W will be described with reference to FIGS. 2A to 3B. The method of forming the pattern on the semiconductor substrate W includes an imprinting method using the template 1 of the first embodiment.

FIGS. 2A to 2D are cross-sectional views partially illustrating a procedure of the imprinting method using the template 1 according to the first embodiment. In FIGS. 2A to 2D, the protective layers 41 and 61, the adhesive layer 51, and the like included in the template 1 are not illustrated.

As illustrated in FIG. 2A, the semiconductor substrate W provided with an alignment mark MKw is prepared. The semiconductor substrate W is, for example, a silicon substrate or the like. The alignment mark MKw includes a protrusion or the like provided on an upper surface of the semiconductor substrate W. In addition to the alignment mark MKw, an alignment mark, an inspection mark, and the like which are not illustrated are also formed on the semiconductor substrate W.

Note that a processed layer such as a silicon oxide layer as a target for forming the pattern may be provided on the semiconductor substrate W. When the processed layer is the target for forming the pattern, a support substrate for supporting the processed layer such as an insulating substrate or a conductive substrate may be used, instead of the semiconductor substrate W.

As illustrated in FIG. 2B, a resist layer 71 covering the upper surface of the semiconductor substrate W is formed. The resist layer 71 is, for example, a photocurable resin or the like that is cured by application of ultraviolet light, and is formed on the semiconductor substrate W in an uncured state. At this time, the resist layer 71 is enabled to be formed on the entire surface of the semiconductor substrate W using spin coating or the like, or is enabled to be formed by dropping a plurality of droplets using a dropping device of inkjet type, or the like.

In addition, the template 1 is arranged so that the pattern 21 of the resin layer 20 faces the semiconductor substrate W. At this time, the alignment mark MKw provided on the semiconductor substrate W and the alignment mark MK of the template 1 are observed from above the template 1 to horizontally adjust a relative position between the semiconductor substrate W and the template 1 so that the alignment marks MKw and MK vertically overlap each other.

In this way, alignment between the semiconductor substrate W and the template 1 performed using the alignment marks MKw and MK in a state where the resist layer 71 of the semiconductor substrate W and the template 1 are not in contact with each other is also referred to as rough alignment.

As illustrated in FIG. 2C, the pattern 21 of the template 1 is pressed against the resist layer 71 on the semiconductor substrate W.

At this time, while a helium gas, a carbon dioxide gas, or the like is injected between the semiconductor substrate W and the template 1, the pattern 21 of the template 1 and the resist layer 71 are brought into contact with each other, in a state where the counterbore 13 provided in a back surface of the template 1 is pressed. Therefore, atmosphere or the like between the semiconductor substrate W and the template 1 is removed by the helium gas or the like, and the vicinity of a horizontal center to the outer peripheral portion of the pattern 21 of the template 1 sequentially and stepwise make into contact with the resist layer 71.

Therefore, it is possible to inhibit the atmosphere from remaining in the pattern 21 of the template 1 when the resist layer 71 makes contact with the template 1, bringing the resist layer 71 into closer contact with the recesses and protrusions of the pattern 21 of the template 1. Note that when the template 1 makes contact with the resist layer 71, the atmosphere remaining in the pattern 21 of the template 1 is mixed into the resist layer 71 to cause transfer failure or the like of the pattern 21, which is also referred to as bubble entrapment or the like.

At this time, a gap is provided between the semiconductor substrate W and the template 1 so that the template 1 is not in direct contact with the semiconductor substrate W to prevent damage of the semiconductor substrate W.

In addition, the semiconductor substrate W and the template 1 are more precisely aligned with alignment marks, which are not illustrated, provided on the semiconductor substrate W and the template 1. This configuration enables use of, for example, alignment marks or the like having a two-dimensional periodic structure having different periods, for the semiconductor substrate W and the template 1. The alignment marks configured as described above are superimposed vertically, enabling observation of interference fringes called moiré. On the basis of a state of the interference fringes, the semiconductor substrate W and the template 1 are enabled to be aligned more precisely.

As described above, more precise alignment between the semiconductor substrate W and the template 1 performed in a state where the resist layer 71 of the semiconductor substrate W and the template 1 are in contact with each other is also referred to as fine alignment.

During the fine alignment, the template 1 being in contact with the resist layer 71 is horizontally slid. In addition, a size error, distortion, and the like may occur in the pattern 21 upon forming the resin layer 20, and therefore, the template 1 is pressed from a side surface thereof to correct the size and distortion of the pattern 21 upon pressing the template 1. As described above, the lateral stress is generated between the resin layer 20 and the mesa portion 11 of the template 1 by the sliding operation during fine alignment, the correction of the pattern 21, and the like.

However, the resin layer 20 and the mesa portion 11 include the anchor patterns 22 and 12, respectively. Therefore, peeling off of the resin layer 20 from the mesa portion 11 is inhibited by these anchor patterns 22 and 12.

When the fine alignment between the semiconductor substrate W and the template 1 is completed, the position of the template 1 with respect to the semiconductor substrate W is fixed, and the resist layer 71 is cured by applying ultraviolet light or the like to the resist layer 71 from above the template 1.

As illustrated in FIG. 2D, after the resist layer 71 is cured, the template 1 is raised to release the pattern 21 of the template 1 from the resist layer 71. Therefore, a resist pattern 71p obtained by transferring the pattern 21 of the template 1 to the resist layer 71 is formed.

Note that when the template 1 is brought into contact with the resist layer 71, a a thin layer of the resist 71r is generated between the template 1 and the semiconductor substrate W, and a bottom of the resist pattern 71p is connected to each other by the thin resist layer 71r.

As described above, the imprinting method using the template 1 of the first embodiment is finished.

FIGS. 3A and 3B are cross-sectional views partially illustrating a procedure of the method of forming the pattern on the semiconductor substrate W according to the first embodiment.

As illustrated in FIG. 3A, the thin layer 71r at the bottom of resist pattern 71p is removed.

As illustrated in FIG. 3B, the semiconductor substrate W is etched using the resist pattern 71p as a mask. Therefore, a desired pattern Wp is formed on the semiconductor substrate W.

At this time, out of the pattern 21 initially included in the resin layer 20 and the recess 24 corresponding to the alignment mark MK, only a portion derived from the pattern 21 may be transferred to the semiconductor substrate W. This is because when the recess 24 of the resin layer 20 is transferred to the resist pattern 71p, a portion of the resist pattern 71p derived from the recess 24 of the resin layer 20 is arranged so as to coincide vertically with the protrusion of the alignment mark MKw of the semiconductor substrate W.

Note that as described above, when the processed layer is provided on the upper surface of the semiconductor substrate W or the like, the pattern 21 of the template 1 is transferred to the processed layer.

Thereafter, the resist pattern 71p is removed by ashing.

As described above, the method of forming the pattern of the first embodiment is finished.

Thereafter, the semiconductor device is manufactured through a film forming process, the imprinting process, a lithography process, an etching process, and the like for the semiconductor substrate W.

### (Method of Manufacturing Template)

Next, a method of manufacturing the template 1 according to the first embodiment will be described with reference to FIGS. 4A to 7C. The method of manufacturing the template 1 includes a method of manufacturing a template mold 100 for forming the resin layer 20 on the quartz substrate 10 of the template 1.

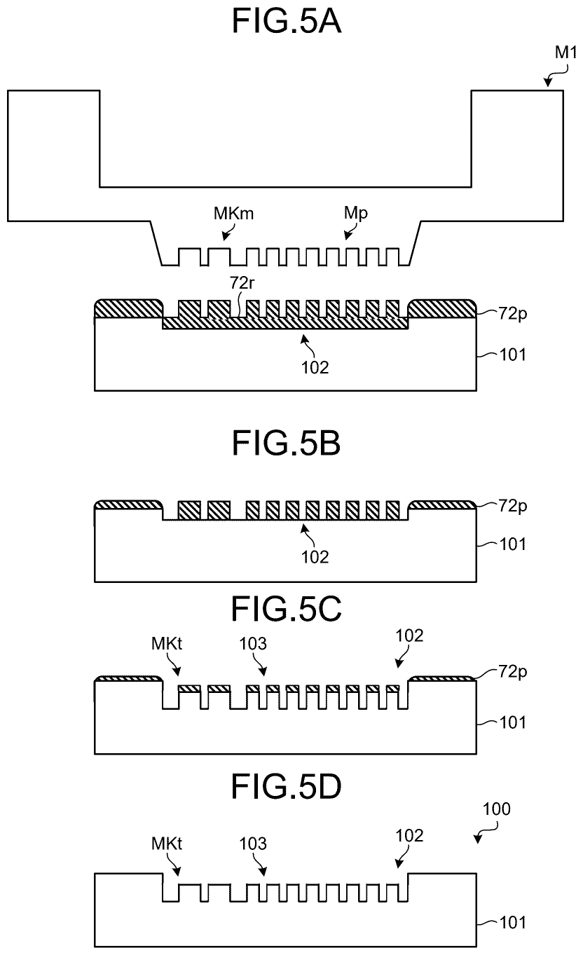

FIGS. 4A to 5D are cross-sectional views sequentially illustrating parts of a procedure of a method of manufacturing a template mold 100 according to the first embodiment.

As illustrated in FIG. 4A, a substrate 101 of the template mold 100 and a master template M1 for processing the substrate 101 are prepared.

The substrate 101 is, for example, a semiconductor substrate such as a silicon substrate. The substrate 101 has an upper surface in which a recess 102 is provided at a center portion.

The master template M1 includes a pattern Mp and a recess MKm in one surface of the quartz substrate. The shape of the pattern Mp corresponds to the pattern 21 included in the template 1 described above. The recess MKm is a portion serving as an alignment mark MKt (see FIG. 5D, etc.) of the template mold 100 used to form the resin layer 20 on the quartz substrate 10 of the template 1. The pattern Mp and the recess MKm of the master template M1 are formed by, for example, electron beam lithography.

In addition to the recess MKm for forming the alignment mark MKt of the template mold 100, the master template M1 may be provided with an alignment mark with a metal layer such as a chromium layer for adjusting alignment, which is not illustrated, used for alignment between the master template M1 and the substrate 101.

A resist layer 72 covering the upper surface of the substrate 101 is formed, and the master template M1 is arranged so as to face the resist layer 72.

As illustrated in FIG. 4B, the pattern Mp of the master template M1 is pressed against the resist layer 72, and ultraviolet light or the like is applied from above the master template M1 to cure the resist layer 72.

As illustrated in FIG. 5A, the master template M1 is released from the resist layer 72. As a result, a resist pattern 72p having a thin layer 72r at a bottom is formed.

As illustrated in FIG. 5B, the thin layer 72r of the resist pattern 72p is removed.

As illustrated in FIG. 5C, the substrate 101 is etched using the resist pattern 72p as a mask. As a result, a predetermined pattern 103 and the alignment mark MKt are formed in the recess 102 of the substrate 101. The alignment mark MKt includes a protrusion that has an inverted shape of the recess MKm of the master template M1.

As illustrated in FIG. 5D, the resist pattern 72p is removed by ashing.

As described above, the template mold 100 of the first embodiment is manufactured.

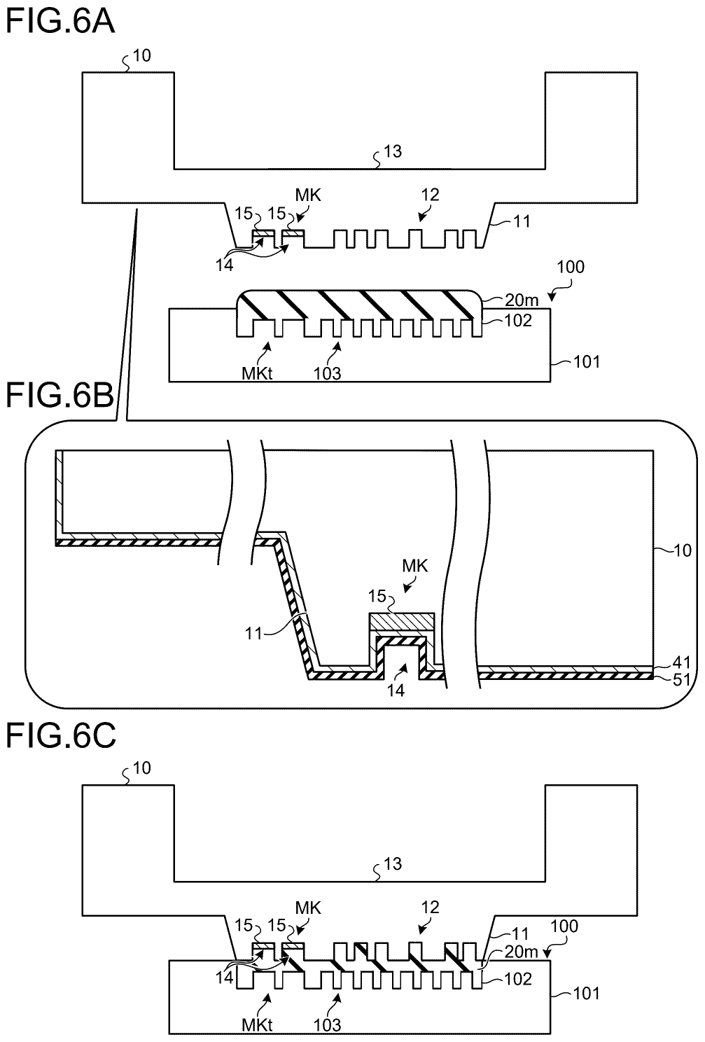

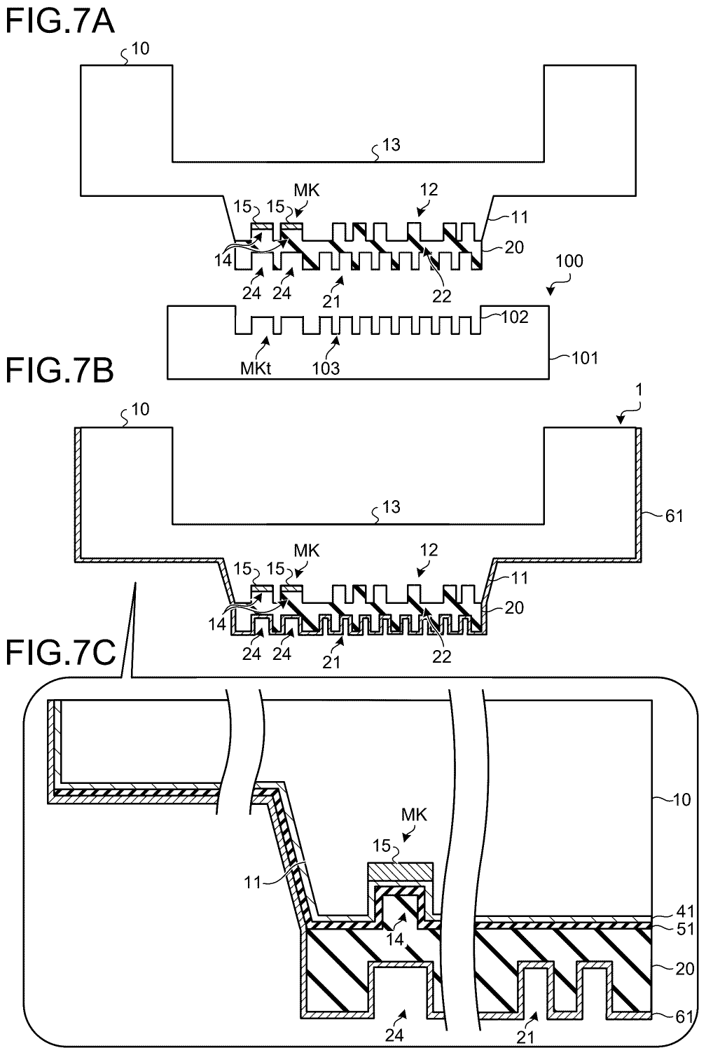

FIGS. 6A to 7C are cross-sectional views sequentially illustrating parts of a procedure of a method of manufacturing a template 1 according to the first embodiment.

As illustrated in FIG. 6A, the quartz substrate 10 of the template 1 is prepared. The quartz substrate 10 is provided with the mesa portion 11 and the counterbore 13, and the mesa portion 11 is provided with the anchor pattern 12, the alignment mark MK, and an alignment mark and an inspection mark which are not illustrated.

The mesa portion 11 and the counterbore 13 of the quartz substrate 10 are formed by, for example, machining. The anchor pattern 12 of the quartz substrate 10 and the recess 14 of the alignment mark MK are formed by, for example, by the imprinting process or the like using a master template on which a corresponding pattern is formed by electron beam drawing. Note that the alignment mark MK, and the alignment mark, the inspection mark, and the like which are not illustrated are also allowed to be formed by the imprinting process without using the electron beam drawing, or by laser processing or the like. The metal layer 15 of the alignment mark MK is formed by, for example, sputtering or the like.

As illustrated in FIG. 6B, the protective layer 41 and the adhesive layer 51 are also formed on the quartz substrate 10. The protective layer 41 is formed using, for example, an atomic layer deposition (ALD) method or the like. When the ALD method is used, the protective layer 41 is continuously formed entirely on the side surface of the quartz substrate 10, the surface provided with the mesa portion 11, the side surface of the mesa portion 11, and the protruding surface of the mesa portion 11. As described above, in the adhesive layer 51, for example, the SOC layer is formed by spin coating or the like. When spin coating is used, the adhesive layer 51 is continuously formed over the entire surface of the quartz substrate 10 except for the side surface.

As illustrated in FIG. 6A, the quartz substrate 10 as described above is opposed to the template mold 100 having a resin layer 20m formed in the recess 102. The resin layer 20m is made of a material of the resin layer 20 such as a silicon-containing resin layer, an acrylic resin layer, or a urethane resin layer, which the template 1 will have, that is, made of an uncured resin. As described above, the recess 102 provided in the substrate 101 illustrated in FIG. 4A facilitates subsequent arrangement of the resin layer 20m in the template mold 100 and adjustment in position upon arrangement thereof. However, the recess 102 may not be provided in the substrate 101.

Furthermore, at this time, the alignment mark MK of the quartz substrate 10 and the alignment mark MKt of the template mold 100 are used to align the quartz substrate 10 and the template mold 100 with each other.

As illustrated in FIG. 6C, the mesa portion 11 of the quartz substrate 10 is pressed against the resin layer 20m of the template mold 100 to perform fine alignment by using unillustrated alignment marks or the like causing moire, and then the resin layer 20m is cured by entire heating or by application of ultraviolet light or the like to a photocurable resin.

As illustrated in FIG. 7A, when the quartz substrate 10 is raised, the resin layer 20 thermally cured or photo-cured and bonded to the mesa portion 11 by the adhesive layer 51 is pulled up together with the quartz substrate 10, and released from the template mold 100.

As illustrated in FIGS. 7B and 7C, the protective layer 61 covering the pattern 21 of the resin layer 20 bonded to the quartz substrate 10 is formed by, for example, the ALD method or the like. When the ALD method is used, the protective layer 61 is continuously formed entirely on the side surface of the quartz substrate 10, the surface provided with the mesa portion 11, the side surface of the mesa portion 11, the side surface of the resin layer 20, and the surface of the resin layer 20 where the pattern 21 is provided.

As described above, the template 1 of the first embodiment is manufactured.

### (Method of Reproducing Template)

The pattern 21 and the like of the resin layer 20 are worn due to repeated use of the template 1 of the first embodiment in the imprinting process. In such a case, the template 1 of the first embodiment is configured to be reproduced by replacing the resin layer 20.

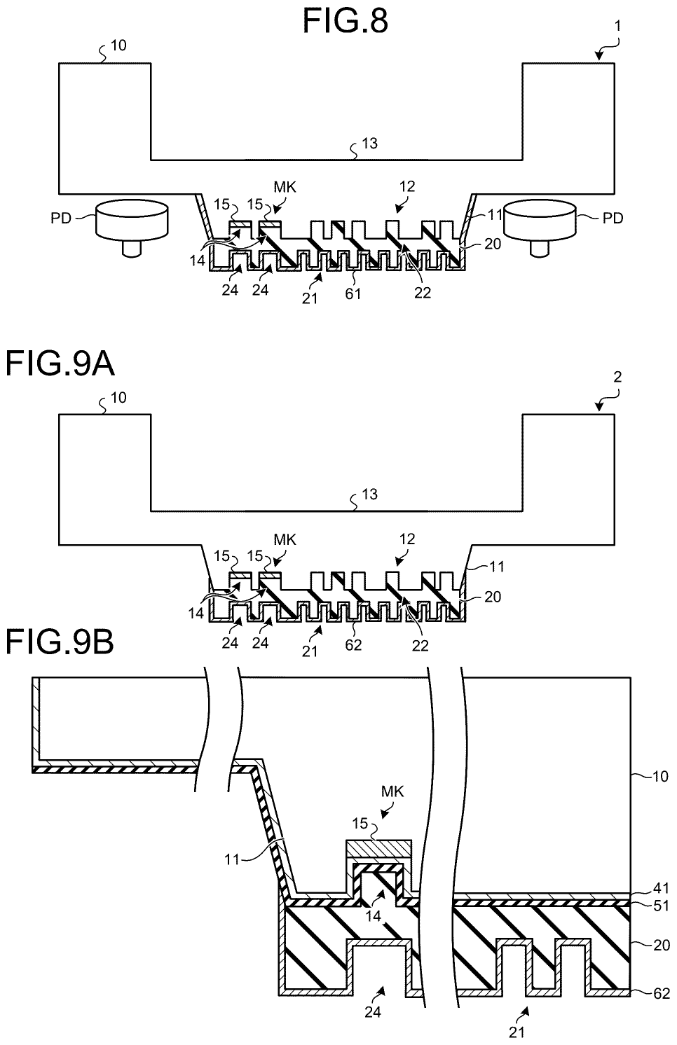

A method for reproducing the template 1 according to the first embodiment will be described below with reference to FIG. 8. FIG. 8 is a cross-sectional view partially illustrating a procedure of the method of reproducing the template 1 according to the first embodiment.

As illustrated in FIG. 8, in the template 1, the protective layer 61 is removed by polishing the surface of the quartz substrate 10 on the side on which the mesa portion 11 is provided by a polishing pad PD or the like, or by using dry etching or the like. As a result, the adhesive layer 51 (see FIG. 1B and the like) is exposed on the surface of the quartz substrate 10. Note that the protective layer 61 is preferably removed not only from the surface on the side on which the mesa portion 11 is provided but also from the side surface of the quartz substrate 10.

The protective layer 61 is the silicon oxide layer or the like similar to the quartz substrate 10, but the quartz substrate 10 is covered with the protective layer 41 (see FIG. 1B etc.). Therefore, when the protective layer 61 is removed, damage to the quartz substrate 10 can be suppressed.

Thereafter, the adhesive layer 51 is removed by ashing, or is dissolved and removed using a solvent or the like. Therefore, the resin layer 20 is peeled off from the quartz substrate 10. Also in this case, the surface of the quartz substrate 10 is protected by the protective layer 41.

Thereafter, the protective layer 41 on the surface of the quartz substrate 10 is removed as necessary. The protective layer 41 in the anchor pattern 12 of the quartz substrate 10 and the recess 14 of the alignment mark MK is allowed to be removed by dissolution using, for example, a solvent. The protective layer 41 on the surface of the quartz substrate 10 on the side on which the mesa portion 11 is provided and on the side surface of the quartz substrate 10 may be removed by, for example, polishing.

As a result, the quartz substrate 10 from which the resin layer 20, the protective layers 41 and 61, the adhesive layer 51, and the like are all removed is obtained. Note that the metal layer 15 provided in the recess 14 of the alignment mark MK is preferably not removed. In addition, the protective layer 41 may remain without being removed.

Then, the quartz substrate 10 is subjected to the above processing of FIGS. 6A to 7C, and therefore, a new resin layer 20 is bonded to the quartz substrate 10, and the template 1 is reproduced.

As described above, the process of reproducing the template 1 according to the first embodiment is finished.

### (Review)

In a manufacturing process for a semiconductor device, an imprinting process using a template is performed in some cases. The template is repeatedly used for the imprinting process, and therefore, a pattern of the template is worn. Therefore, an attempt has been made to form the pattern of the template on a replaceable resin layer to reproduce the template. The pattern of the resin layer is provided with a protective layer such as a silicon oxide layer to increase strength and suppress wearing out of the pattern.

However, there is a problem that it is difficult to peel off the resin layer on which the protective layer is formed, from a quartz substrate of the template during a process of reproducing the template.

In addition, an alignment mark including a metal layer is formed on the template, for alignment with a semiconductor substrate or the like. However, in the template having the resin layer, it may be difficult to form the metal layer on a surface of the resin layer depending on the type of resin. Furthermore, the alignment mark of the template, not limited to the template having the resin layer, may interfere with an alignment mark causing moire used for fine alignment, making observation of interference fringes generated by the alignment marks.

The template 1 of the first embodiment includes the protective layer 61 that covers the surface of the resin layer 20 where the pattern 21 is provided. This configuration enables increased strength of the pattern 21, and suppression of wearing out of the pattern 21.

The template 1 of the first embodiment includes the resin layer 20 that is bonded to the protective layer 41 covering the quartz substrate 10 by the adhesive layer 51 and has the pattern 21 on the surface opposite to the bonding surface to the protective layer 41. As described above, even if the protective layer 61 is formed on the resin layer 20, the resin layer 20 bonded to the quartz substrate 10 by the adhesive layer 51 in this manner is allowed to be readily peeled off, during the process of reproducing the template 1. In addition, when the adhesive layer 51 is removed and the resin layer 20 is peeled off during the process of reproducing the template 1, the protective layer 41 covering the quartz substrate 10 enables protection of the surface of the quartz substrate 10.

In addition, in recent semiconductor devices manufactured by the imprinting process and the like, high-mix low-volume manufacturing is growing. As described above, the template 1 having a structure in which the resin layer 20 being readily replaceable has the pattern 21 enables to readily change the pattern formed by the imprinting process in response to the high-mix low-volume manufacturing of the semiconductor devices.

The template 1 of the first embodiment includes the alignment mark MK that is provided on the quartz substrate 10 and includes the metal layer 15. Forming the metal layer 15 not on the resin layer 20 but on the quartz substrate 10 in this way facilitates formation of the metal layer 15.

In addition, the metal layer 15 interposed between the quartz substrate 10 and the resin layer 20 prevents transfer of the alignment mark MK to the semiconductor substrate W, unlike the metal layer 15 formed on, for example, the surface of the resin layer 20. Therefore, it is possible to select the size, shape, and the like of the alignment mark MK so as to increase the degree of freedom in design of the alignment mark MK and suppress interference with the alignment mark causing moire used for fine alignment.

According to the template 1 of the first embodiment, the quartz substrate 10 and the resin layer 20 have the anchor patterns 12 and 22 including the recesses and protrusions that can be fitted to each other, respectively, on the respective bonding surfaces. As described above, in the fine alignment, and the correction of the pattern 21, performed during the imprinting process, the lateral stress is generated between the quartz substrate 10 and the resin layer 20. Providing the anchor patterns 12 and 22 as described above enables to sufficiently increase the adhesive strength between the resin layer 20 and the quartz substrate 10, even when the resin layer 20 is formed on the quartz substrate 10, for example, by adhesion, and suppress peeling off of the resin layer 20 during the use of the template 1.

According to the template 1 of the first embodiment, the recess of each of the anchor patterns 12b and 22c have a tapered shape that narrows from the bottom surface of the recess toward the open end of the recess, and the protrusion of each of the anchor patterns 12c and 22b has a tapered shape that widens from the base portion of the protrusion toward an upper end of the protrusion. Therefore, the anchor patterns 12b and 22b or the anchor patterns 12c and 22c are combined in a wedged manner, and it is possible to further increase the adhesive strength between the resin layer 20 and the quartz substrate 10.

According to the template 1 of the first embodiment, the adhesive layer 51 continuously covers the bonding surface of the mesa portion 11, the side surface of the mesa portion 11, and one surface of the quartz substrate 10. The adhesive layer 51 configured as described above is formed by, for example, spin coating or the like. As described above, using the spin coating facilitates formation of the adhesive layer 51.

### (First Modification)

Next, a template 2 according to a first modification of the first embodiment will be described with reference to FIGS. 9A and 9B. In the template 2 of the first modification, the shape of a protective layer 62 is different from the shape of the protective layer 61 of the first embodiment described above.

FIGS. 9A and 9B are schematic diagrams illustrating an exemplary configuration of the template 2 according to the first modification of the first embodiment. More specifically, FIG. 9A is a cross-sectional view illustrating the whole of the template 2, and FIG. 9B is a partially enlarged cross-sectional view of the template 2.

Note that in FIGS. 9A and 9B, the same reference numerals are assigned to configurations similar to those of the above first embodiment, and the description thereof may not be repeated.

As illustrated in FIGS. 9A and 9B, the template 2 of the first modification includes the protective layer 62 that covers only the resin layer 20. In other words, the protective layer 62 continuously covers the surface of the resin layer 20 where the pattern 21 is provided and the side surface thereof. However, unlike the above first embodiment, the adhesive layer 51 arranged via the protective layer 41 is exposed on each side surface of the mesa portion 11 and a surface of the quartz substrate 10 on the side on which the mesa portion 11 is provided, and the protective layer 41 directly covering each side surface of the quartz substrate 10 is exposed on the side surface of the quartz substrate 10.

The protective layer 62 configured as described above is allowed to be formed using the resin layer 20 made of a silicon-containing resin. In other words, silicon-containing resin layer 20 from the surface to a predetermined depth is subjected to oxidation treatment. As a result, the protective layer 62, which is a silicon oxide rich layer or the like, is formed on the surface of the resin layer 20.

In addition, it is also possible to form the protective layer 62 containing a large amount of silicon on the surface by removing components other than silicon on the surface of the resin layer 20, instead of the oxidation treatment of silicon-containing resin layer 20.

During a process of reproducing the template 2 according to the first modification, the adhesive layer 51 exposed on the surface of the quartz substrate 10 can be removed by ashing or dissolution without removing the protective layer 62.

According to the template 2 of the first modification, the formation of the protective layer 62 includes oxidation of the surface of the resin layer 20 which is a silicon-containing resin layer, to a predetermined depth of the template 2. Alternatively, the formation of the protective layer 62 includes removing components other than silicon on the surface of the resin layer 20. Accordingly, an effect similar to that of the template 1 of the first embodiment is provided.

### (Second Modification)

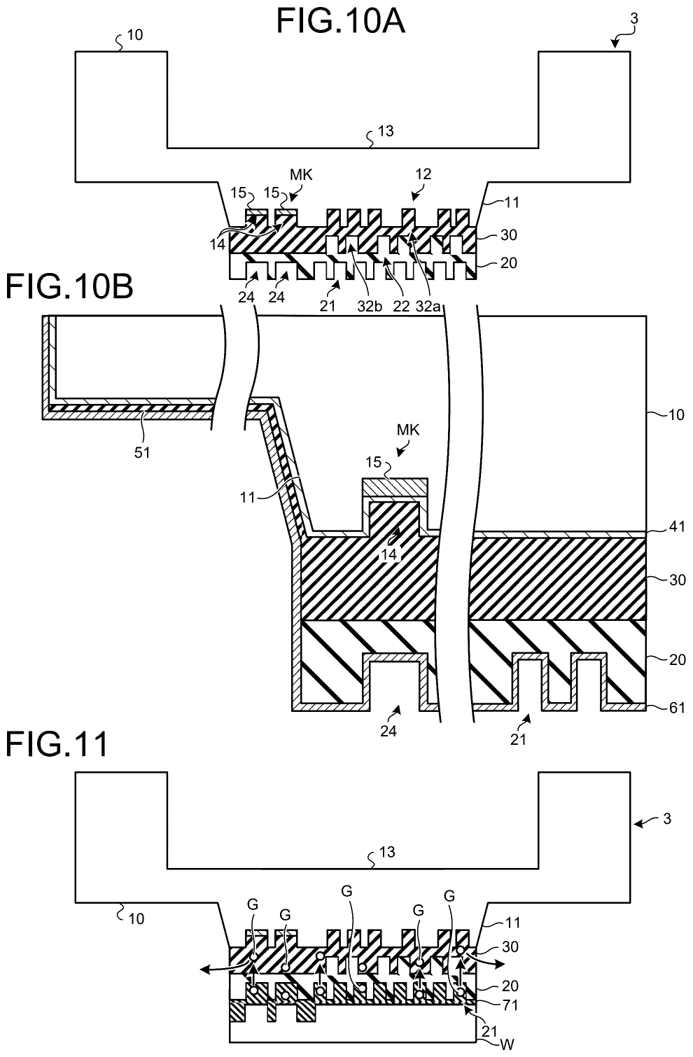

Next, a template 3 according to a second modification of the first embodiment will be described with reference to FIGS. 10A to 13B. Unlike the first embodiment, the template 3 of the second modification includes two types of the resin layer 20 and resin layer 30.

Note that in the following drawings, the same reference numerals are assigned to configurations similar to those of the above first embodiment, and the description thereof may not be repeated.

FIGS. 10A and 10B are schematic diagrams illustrating an exemplary configuration of the template 3 according to the second modification of the first embodiment. More specifically, FIG. 10A is a cross-sectional view illustrating the whole of the template 3, and FIG. 10B is a partially enlarged cross-sectional view of the template 3.

As illustrated in FIG. 10A, the template 3 of the second modification includes the resin layer 30 between the resin layer 20 and the quartz substrate 10. The resin layer 30 is a layer having a gas permeability higher than that of the resin layer 20, such as an SOC layer or a porous resin layer.

Furthermore, the resin layer 30 includes an anchor pattern 32a that is fitted to the anchor pattern 12 of the quartz substrate 10, on a surface on the side of the quartz substrate 10, and an anchor pattern 32b that is fitted to the anchor pattern 22 of the resin layer 20, on a surface on the side of the resin layer 20. These anchor patterns 32a and 32b are also allowed to have any of various shapes illustrated in FIGS. 1C to 1F and the like of the above first embodiment, such as a vertical recess or protrusion or a tapered recess or protrusion.

As illustrated in FIG. 10B, in the template 3 of the third modification, the protective layer 41 and the adhesive layer 51 are provided in this order between the resin layer 30 and the quartz substrate 10.

However, when the resin layer 30 includes a material similar to that of the adhesive layer 51, such as an SOC layer, the template 3 may not have the adhesive layer 51. In this configuration, an interface between the resin layer 30 and the mesa portion 11 functions as the adhesive layer 51. In reproduction of the template 3 as well, removal of an interface portion between the resin layer 30 and the mesa portion 11 by ashing, dissolution, or the like enables peeling off of the resin layers 20 and 30 from the quartz substrate 10 collectively.

As described above, the template 3 includes the resin layer 30 having a high gas permeability, and therefore, it is possible to further reduce bubble entrapment between the template 3 and the resist layer on the semiconductor substrate during the imprinting process using the template 3.

FIG. 11 is a cross-sectional view partially illustrating a procedure of an imprinting method using the template 3 according to the second modification of the first embodiment.

As illustrated in FIG. 11, when the template 3 is pressed against the resist layer 71 on the semiconductor substrate W, the helium gas or the like is injected between the template 3 and the semiconductor substrate W, and the counterbore 13 portion is pressed from the back surface of the template 3 so that the pattern 21 of the template 3 is adjusted to make contact with the resist layer 71 on the semiconductor substrate W in order from the vicinity of the horizontal center, as described above, for suppressing the bubble entrapment due to the atmosphere or the like.

However, even when the above measures are taken, the atmosphere or a gas G such as helium gas may remain in the recesses and protrusions or the like of the pattern 21 of the template 3. The template 3 of the third modification includes the resin layer 30 having a high gas permeability, and therefore, the gas G remaining as described above is discharged to the outside from between the template 3 and the semiconductor substrate W, via the resin layer 30.

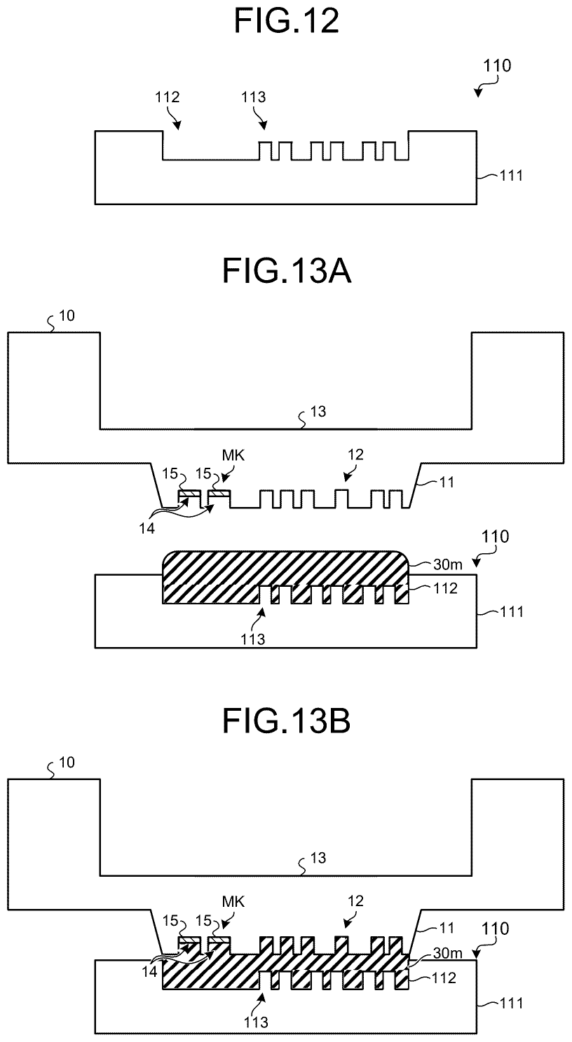

The template 3 of the second modification as described above is manufactured by a process illustrated in FIGS. 12 to 15 by using a template mold 110 having a pattern of the resin layer 30 of the second modification, in addition to the template mold 100 of the above first embodiment.

FIG. 12 is a cross-sectional view illustrating an exemplary configuration of the template mold 110 used for manufacturing the template 3 according to the second modification of the first embodiment.

As illustrated in FIG. 12, the template mold 110 includes a substantially flat substrate 111. The substrate 111 includes a recess 112 at a horizontal center of an upper surface thereof. In the recess 112 of the substrate 111, a pattern 113 corresponding to the anchor pattern 32b of the resin layer 30 is provided.

The template mold 110 configured as described above is allowed to be manufactured using a master template or the like on which a pattern corresponding to the pattern included in the recess 112 of the template mold 110 is formed, as in the template mold 100 of the above first embodiment.

FIGS. 13A to 15 are cross-sectional views sequentially illustrating parts of a procedure of a method of manufacturing the template 3 according to the second modification of the first embodiment.

As illustrated in FIG. 13A, a resin layer 30m being uncured is formed in the recess 112 of the template mold 110 described above.

Furthermore, the quartz substrate 10 in which the anchor pattern 12, the alignment mark MK including the metal layer 15 in the recess 14, the protective layer 41, and the adhesive layer 51 are formed is opposed to the template mold 110 having the resin layer 30m being uncured, formed to cover the inside of the recess 112.

As illustrated in FIG. 13B, the mesa portion 11 of the quartz substrate 10 is pressed against the resin layer 30m of the template mold 110 to cure the resin layer 30m by entire heating or by application of ultraviolet light or the like.

Note that at this time, the resin layer 30 is a resin layer having a high gas permeability, and therefore, there is also an advantage that bubble entrapment between the resin layer 30 and the quartz substrate 10 is suppressed.

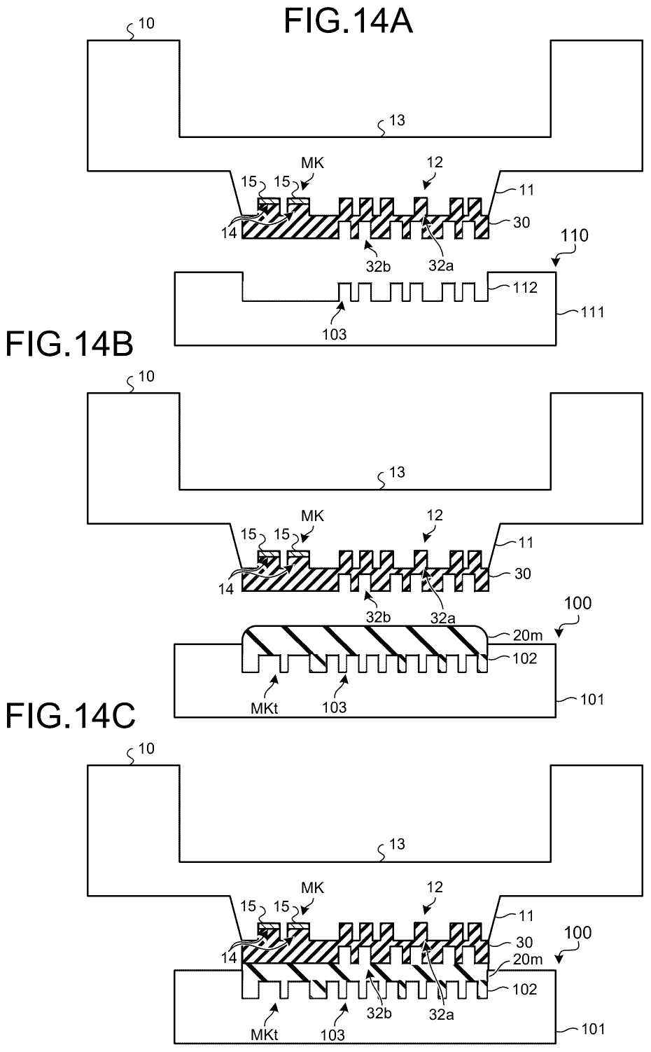

As illustrated in FIG. 14A, when the quartz substrate 10 is raised, the resin layer 30 thermally cured or photo-cured and bonded to the mesa portion 11 by the adhesive layer 51 is pulled up together with the quartz substrate 10, and released from the template mold 110.

Therefore, the resin layer 30 having the anchor pattern 32b on a surface released from the template mold 110 and having the anchor pattern 32a fitted to the anchor pattern 12 of the quartz substrate 10 on the bonding surface to the quartz substrate 10 is formed in a state of being bonded to the quartz substrate 10.

As illustrated in FIG. 14B, the quartz substrate 10 on which the resin layer 30 is opposed to the template mold 100 in which the resin layer 20m being uncured is formed in the recess 102.

Furthermore, at this time, the alignment mark MK of the quartz substrate 10 and the alignment mark MKt of the template mold 100 are used to align the quartz substrate 10 and the template mold 100 with each other.

As illustrated in FIG. 14C, the resin layer 30 of the quartz substrate 10 is pressed against the resin layer 20m of the template mold 100 to perform fine alignment by using unillustrated alignment marks or the like causing moire, and then the resin layer 20m is cured by entire heating or application of ultraviolet light or the like.

Note that at this time, the resin layer 30 is a resin layer having a high gas permeability, and therefore, there is also an advantage that bubble entrapment between the resin layer 30 and the resin layer 20 is suppressed.

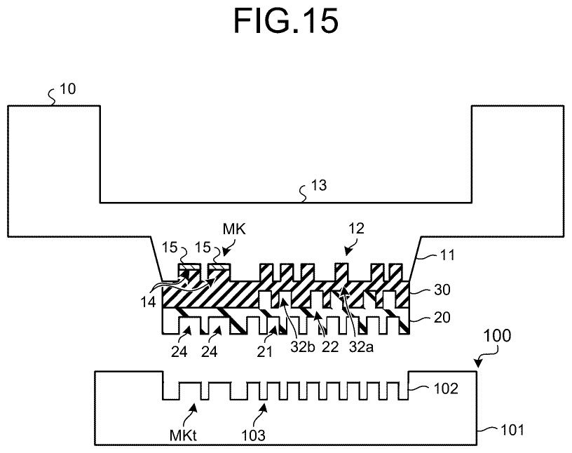

As illustrated in FIG. 15, when the quartz substrate 10 is raised, the resin layer 20 thermally cured or photo-cured and bonded to the resin layer 30 is pulled up together with the quartz substrate 10, and released from the template mold 100.

As described above, in the template 3 including the resin layer 30 having a high gas permeability, bubble entrapment in a stacked structure of the resin layers 20 and 30 and the quartz substrate 10 are allowed to be suppressed not only during the imprinting process for the semiconductor substrate W by using the template 3 but also during manufacturing.

Thereafter, the protective layer 61 covering the pattern 21 of the resin layer 20, the quartz substrate 10, and the like is formed by, for example, the ALD method or the like. However, the protective layer 62 of the above first modification may be formed on the surface of the resin layer 20 where the pattern 21 is formed by using the silicon-containing resin for the resin layer 20, and oxidizing silicon-containing resin on the surface of the resin layer 20 or removing components other than silicon on the surface.

As described above, the template 3 of the second modification is manufactured.

The template 3 of the second modification includes the resin layer 20 having a pattern and the resin layer 30 having the bonding surface to the quartz substrate 10, interposed between the resin layer 20 and the quartz substrate 10, and having a gas permeability higher than that of the resin layer 20. This configuration makes it possible to further suppress bubble entrapment during the imprinting process.

According to the template 3 of the second modification, an effect similar to that of the template 1 of the first embodiment is provided.

Note that in the above second modification, the template 3 is manufactured using the two types of template molds 110 and 100. However, the template 3 including the resin layer 30 having a high gas permeability may be manufactured using only the template mold 100. In this case, also when the resin layer 30 is formed by the processing of FIGS. 13A to 14A described above, the template mold 100 is allowed to be used.

However, in this case, the anchor pattern 32b of the resin layer 30 on the side of the resin layer 20 side has the same pattern as that on a surface of the resin layer 20 making contact with the semiconductor substrate W during the imprinting process. In other words, the anchor pattern 32b of the resin layer 30 has a pattern corresponding to the pattern 21 of the resin layer 20 used for transfer, and the recess 24 formed in association with the alignment mark MKt of the template mold 100.

Thereafter, the template 3 is manufactured using only the template mold 100 by performing the above processing subsequent to FIG. 14B. In this case, the anchor pattern 22 of the resin layer 20 also corresponds to the anchor pattern 32b of the resin layer 30, and the resin layer 20 itself has a pattern reversed in recesses and protrusions from the pattern 21 and the recess 24 on a contact surface with the semiconductor substrate W.

### (Third Modification)

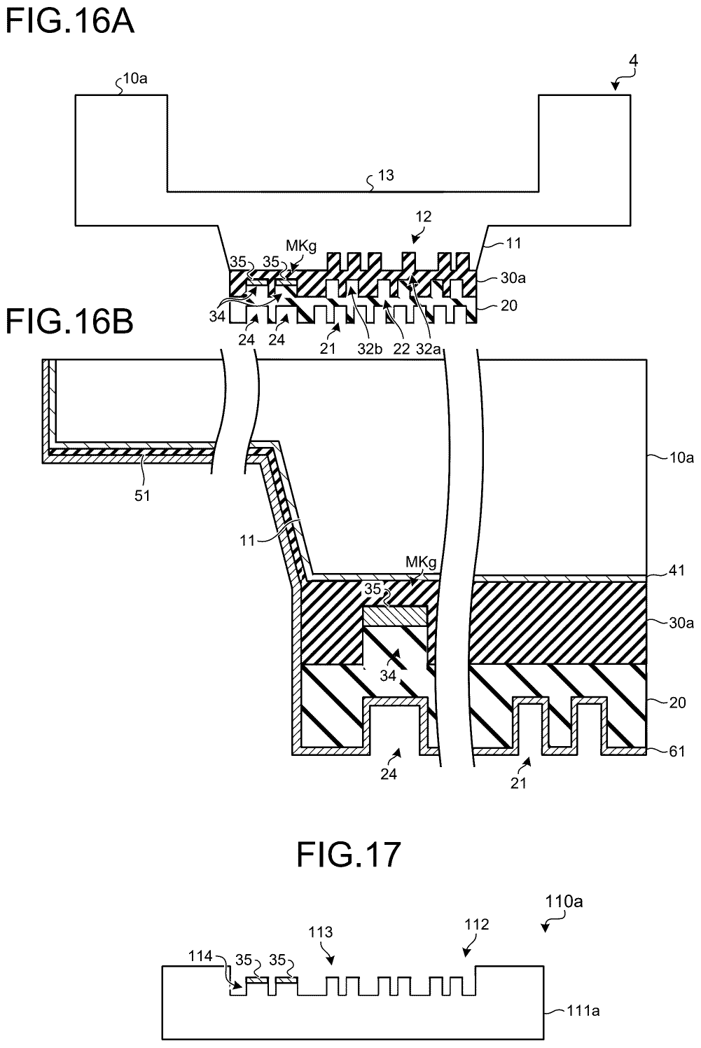

Next, a template 4 of the third modification of the first embodiment will be described with reference to FIGS. 16A to 19C. In the template 4 of the third modification, an arrangement position of an alignment mark MKg is different from the arrangement position of the alignment mark MK of the above second modification.

Note that in the following drawings, the same reference numerals are assigned to configurations similar to those of the above second modification, and the description thereof may not be repeated.

FIGS. 16A and 16B are schematic diagrams illustrating an exemplary configuration of the template 4 according to the third modification of the first embodiment. More specifically, FIG. 16A) is a cross-sectional view illustrating the whole of the template 4, and FIG. 16B is a partially enlarged cross-sectional view of the template 4.

As illustrated in FIG. 16A, the template 4 of the third modification includes a quartz substrate 10a, a resin layer 30a, the resin layer 20, and the like.

Unlike the quartz substrate 10 according to the second modification described above, the quartz substrate 10a does not have the alignment mark MK. In the quartz substrate 10 of the above second modification, the quartz substrate 10a has, for example, a flat surface instead of an area where the alignment mark MK has been arranged.

The resin layer 30a has the alignment mark MKg in addition to the configurations of the resin layer 30 of the above second modification. The alignment mark MKg includes a recess 34 provided on the bonding surface of the resin layer 30a to the resin layer 20, and a metal layer 35 such as a chromium layer provided on a bottom surface of the recess 34. The recess 24 of the resin layer 20 which has been arranged at the position vertically overlapping the alignment mark MK of the quartz substrate 10, in the above second modification is arranged at a position vertically overlapping the alignment mark MKg of the resin layer 30a, in the template 4 of the third modification.

As illustrated in FIG. 16B, the resin layer 30a and the resin layer 20 are directly bonded to each other, as in the second modification described above. Therefore, the recess 34 of the alignment mark MKg of the resin layer 30a is filled with the resin layer 20. The resin layer 20 in the recess 34 is in contact with each of side surfaces of the recess 34 and a surface of the metal layer 35 arranged on the bottom surface of the recess 34.

The template 4 of the third modification as described above is manufactured by a process illustrated in FIGS. 17 to 19C by using a template mold 110a having a pattern of the resin layer 30a of the third modification, in addition to the template mold 100 of the above first embodiment.

FIG. 17 is a cross-sectional view illustrating an exemplary configuration of the template mold 110a used for manufacturing the template 4 according to the third modification of the first embodiment.

As illustrated in FIG. 17, the template mold 110a includes a substantially flat substrate 111a. The substrate 111a includes the recess 112 at a horizontal center of an upper surface thereof. In the recess 112 of the substrate 111a, the pattern 113 corresponding to the anchor pattern 32b of the resin layer 30a and a protrusion 114 corresponding to the alignment mark MKg are provided. Furthermore, the protrusion 114 of the substrate 111a has an upper surface provided with the metal layer 35 such as a chromium layer.

The template mold 110a configured as described above is allowed to be manufactured using a master template or the like on which a pattern corresponding to the pattern included in the recess 112 of the template mold 110a is formed, as in the template mold 110 of the above second modification. The metal layer 35 on the upper surface of the protrusion 114 is obtained by forming a mask pattern or the like having an opening in the upper surface of the protrusion 114, on the upper surface of the substrate 111a and then forming a chromium layer or the like by sputtering.

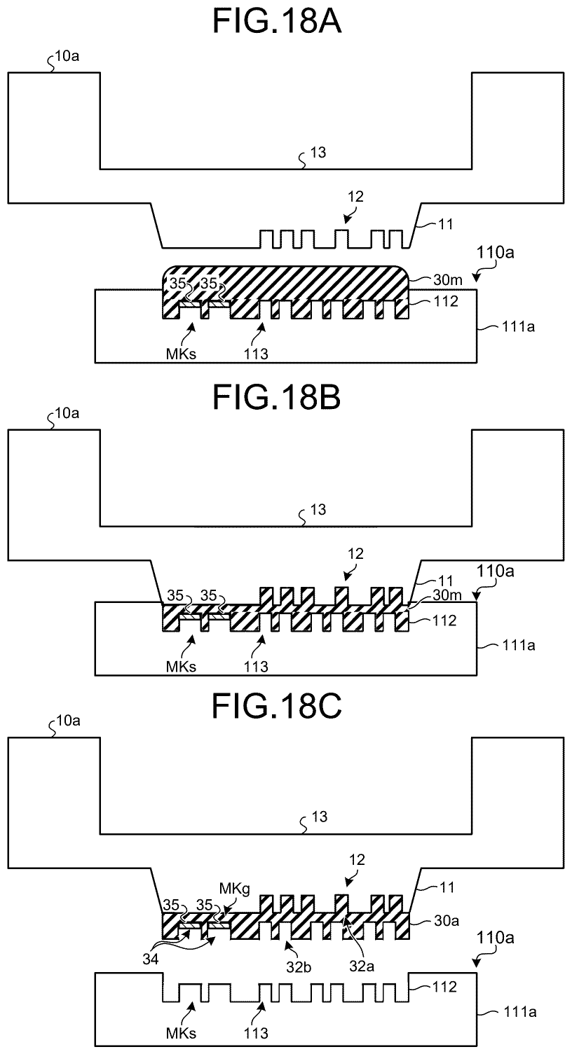

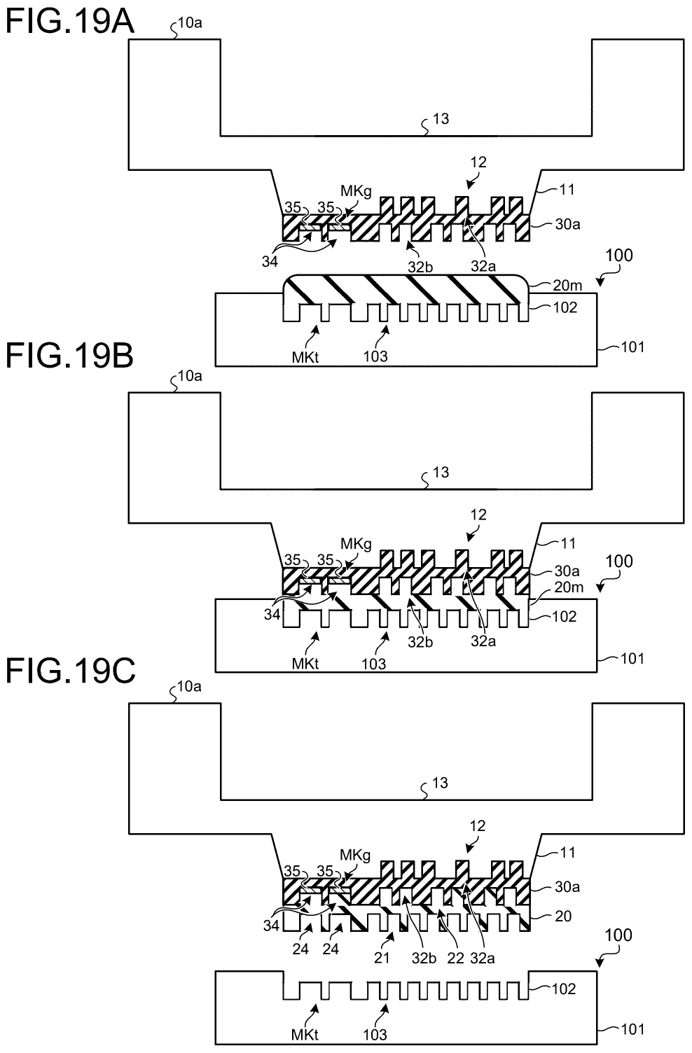

FIGS. 18A to 19C are cross-sectional views sequentially illustrating parts of a procedure of a method of manufacturing the template 4 according to the third modification of the first embodiment.

As illustrated in FIG. 18A, the resin layer 30m being uncured is formed in the recess 112 of the template mold 110a including the pattern 113, the protrusion 114, and the metal layer 35.

Furthermore, the quartz substrate 10a in which the anchor pattern 12, the protective layer 41, and the adhesive layer 51 are formed is opposed to the template mold 110a having the resin layer 30m being uncured, formed to cover the inside of the recess 112 is formed.

As illustrated in FIG. 18B, the mesa portion 11 of the quartz substrate 10a is pressed against the resin layer 30m of the template mold 110a to cure the resin layer 30m by entire heating or by application of ultraviolet light or the like.

As illustrated in FIG. 18C, when the quartz substrate 10a is raised, the resin layer 30a thermally cured or photo-cured and bonded to the mesa portion 11 by the adhesive layer 51 is pulled up together with the quartz substrate 10a, with the metal layer 35 having formed in the template mold 110a adhering, and released from the template mold 110a.

Therefore, the resin layer 30a in which the anchor pattern 32b, and the alignment mark MKg including the recess 34 and the metal layer 35 are provided on a surface released from the template mold 110a, and the anchor pattern 32a fitted to the anchor pattern 12 of the quartz substrate 10a is provided on the bonding surface to the quartz substrate 10a is formed in a state of being bonded to the quartz substrate 10a.

As illustrated in FIG. 19A, the quartz substrate 10a on which the resin layer 30a is formed is opposed to the template mold 100 in which the resin layer 20m being uncured is formed in the recess 102.

Furthermore, at this time, the alignment mark MKg of the resin layer 30a and the alignment mark MKt of the template mold 100 are used to align the quartz substrate 10a and the template mold 100 with each other.

As illustrated in FIG. 19B, the resin layer 30a of the quartz substrate 10a is pressed against the resin layer 20m of the template mold 100 to perform fine alignment by using unillustrated alignment marks or the like causing moire, and then the resin layer 20m is cured by entire heating or application of ultraviolet light or the like.

As illustrated in FIG. 19C, when the quartz substrate 10a is raised, the resin layer 20 thermally cured or photo-cured and bonded to the resin layer 30a is pulled up together with the quartz substrate 10a, and released from the template mold 100.

Thereafter, the protective layer 61 covering the pattern 21 of the resin layer 20, the quartz substrate 10a, and the like is formed by, for example, the ALD method or the like. However, the protective layer 62 of the above first modification may be formed on the surface of the resin layer 20 where the pattern 21 is formed by using the silicon-containing resin for the resin layer 20, and oxidizing silicon-containing resin on the surface of the resin layer 20 or removing components other than silicon on the surface.

As described above, the template 4 of the third modification is manufactured.

The template 4 of the third modification includes the alignment mark MKg that is arranged at a position not overlapping the pattern 21 vertically and having the metal layer 35 between the resin layer 20 and the resin layer 30a. Transfer of the alignment mark MKg to the semiconductor substrate W is prevented by such a configuration as well. Therefore, it is possible to select the size, shape, and the like of the alignment mark MKg so as to increase the degree of freedom in design of the alignment mark MKg and suppress interference with the alignment mark causing moire used for fine alignment.

According to the template 4 of the third modification, an effect similar to that of the above second modification is provided.

Note that the template 4 of the above third modification may also be manufactured using only the template mold 100 as well.

### (Other Modifications)

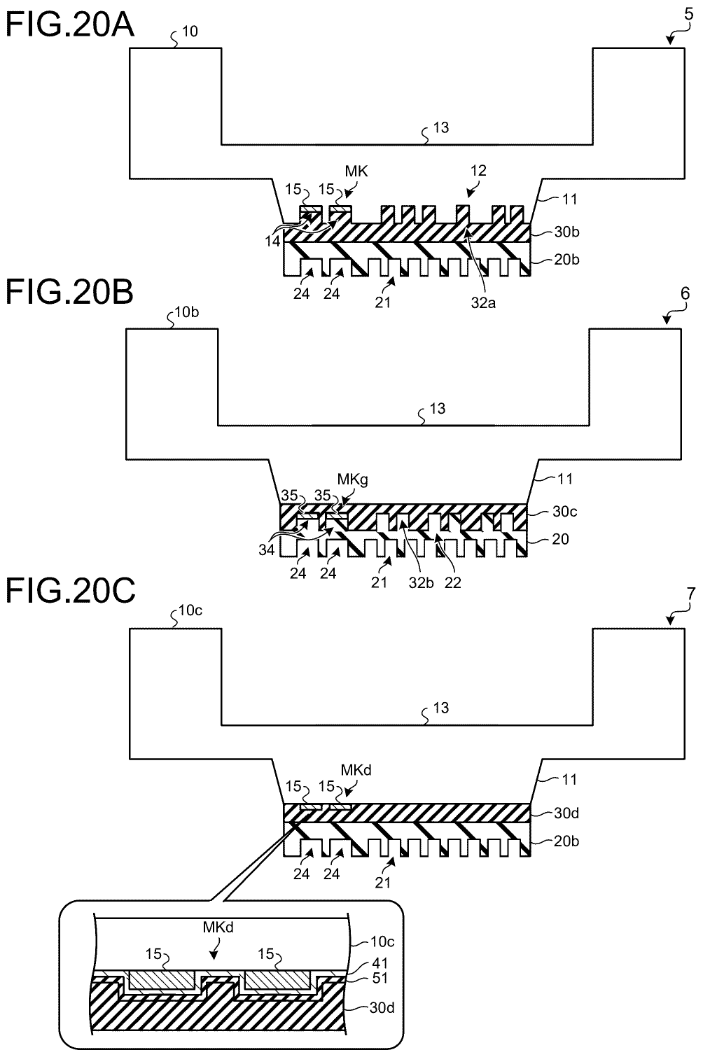

Note that in the first embodiment and the first to third modifications described above, the anchor patterns 12,32a, 32b, 22, and the like are provided on the bonding surfaces of the respective layers such as the quartz substrate 10, the resin layer 30, and the resin layer 20. However, the anchor patterns 12,32a, 32b, and 22 may not be necessarily provided. The following FIGS. 20A to 20C illustrate several examples of a template having no anchor pattern.

FIGS. 20A to 20C are schematic diagrams illustrating an exemplary configurations of templates 5 to 7 according to other modifications of the first embodiment.

In the example of FIG. 20A, the template 5 does not include the anchor patterns 32b and 22 of the above second modification or the like, between a resin layer 30b and a resin layer 20b, and opposed surfaces of the resin layer 30b and the resin layer 20b have flat surfaces.

In the example of FIG. 20B, the template 6 does not include the anchor patterns 12 and 32a of the above third modification or the like, between a quartz substrate 10b and a resin layer 30c, and the opposed surfaces of the quartz substrate 10b and the resin layer 30c have flat surfaces.

In the example of FIG. 20C, the template 7 does not have the anchor patterns 12, 32a, 32b, and 22 of the above second modification or the like, between a quartz substrate 10c and a resin layer 30d or between the resin layer 30d and the resin layer 20b, and the opposed surfaces of the quartz substrate 10c and the resin layer 30d, and the resin layer 30d and the resin layer 20b have flat surfaces. In this configuration, an alignment mark MKd of the quartz substrate 10c includes the metal layer 15 on a flat surface of the quartz substrate 10c. The metal layer 15 on the flat quartz substrate 10c is covered with the protective layer 41 and the adhesive layer 51.

Note that, in addition to the examples of FIGS. 20A to 20C, for example, in the above first embodiment, a configuration without the anchor patterns 12 and 22 between the quartz substrate 10 and the resin layer 20 can be provided.

### Second Embodiment

As described above, in recent semiconductor devices, high-mix low-volume manufacturing is growing. Therefore, for example, it is preferable to facilitate pattern change for the template mold 100 used for manufacturing the template 1 or the like of the above first embodiment as well.

Hereinafter, a second embodiment will be described in detail with reference to the drawings. In the second embodiment, a template mold for which pattern change is facilitated will be described.

### (Method of Manufacturing Template Mold)

In order to facilitate pattern change for the template mold, for example, a configuration can be used in which a silicon oxide layer having a pattern, or the like is formed on a substrate. The silicon oxide layer is readily processed than the substrate, and removal of the silicon oxide layer and formation of a new silicon oxide layer or the like facilitates pattern change.

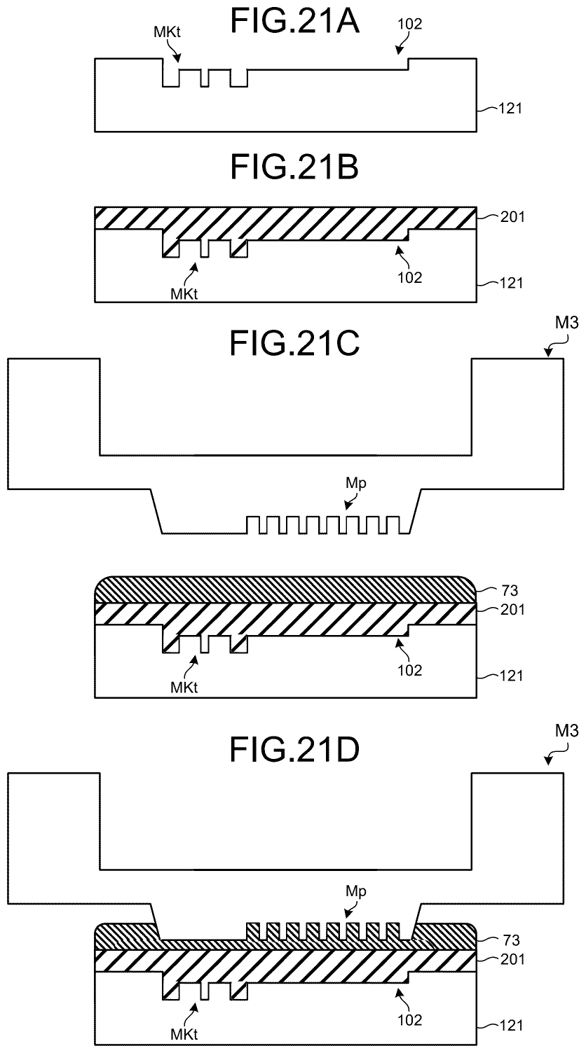

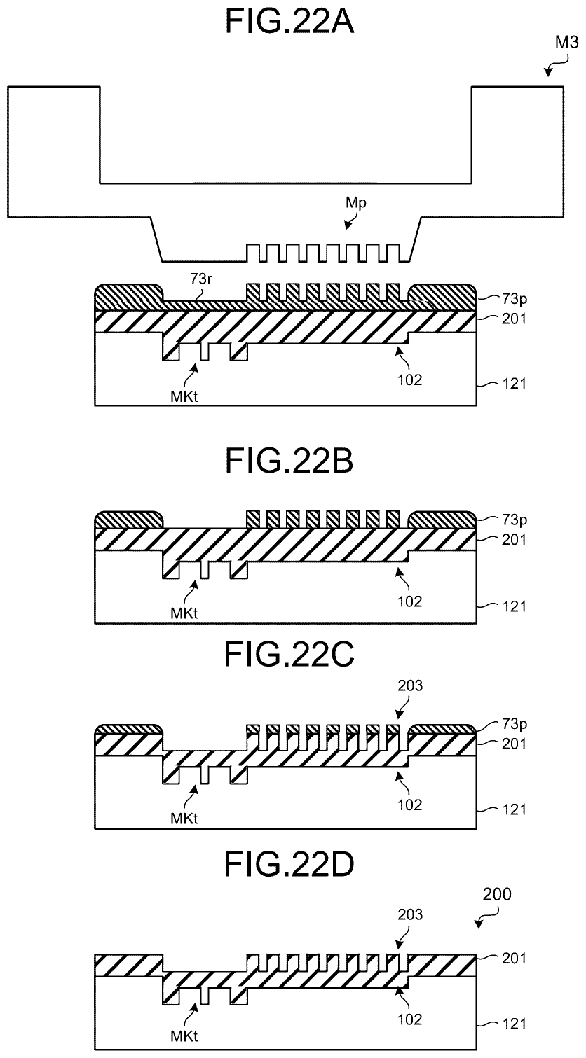

A method of manufacturing a template mold 200 according to the second embodiment will be described below with reference to FIGS. 21A to 22D.

FIGS. 21A to 22D are cross-sectional views sequentially illustrating parts of a procedure of a method of manufacturing the template mold 200 according to the second embodiment.

As illustrated in FIG. 21A, a flat substrate 121 is prepared. The substrate 121 has a configuration for which the pattern 103 is removed from the substrate 101 included in the template mold 100 of the above first embodiment. In other words, in the substrate 121, the recess 102 provided in an upper surface of the substrate 121 and the alignment mark MKt having protrusions provided in the recess 102 are formed.

As illustrated in FIG. 21B, a pattern layer 201 covering the upper surface of the substrate 121 is formed. The pattern layer 201 is, for example, a silicon oxide layer such as a tetra-ethyl ortho-silicate (TEOS) layer, and a pattern corresponding to a pattern that a template manufactured from the template mold 200 will have is formed.

As illustrated in FIG. 21C, a master template M3 is prepared. The master template M3 has a configuration for which the recess MKm is removed from the master template M1 for manufacturing the template mold 100 according to the first embodiment described above. In other words, the pattern Mp corresponding to the pattern that the template manufactured from the template mold 200 will have is formed in the quartz substrate of the master template M3.

Here, it is necessary to adjust the position of the pattern Mp relative to the alignment mark MKt, and therefore, the master template M3 and the substrate 121 preferably have alignment marks, which are not illustrated, for alignment between the master template M3 and the substrate 121.

In addition, a resist layer 73 covering an upper surface of the pattern layer 201 is formed on the substrate 121, and the master template M3 is arranged so as to face the resist layer.

As illustrated in FIG. 21D, the pattern Mp of the master template M3 is pressed against the resist layer 73, and ultraviolet light or the like is applied from above the master template M3 to cure the resist layer 73. At this time, the master template M3 and the substrate 121 are aligned.

As illustrated in FIG. 22A, the master template M3 is released from the resist layer 73. As a result, a resist pattern 73p having a thin layer 73r at a bottom is formed.

As illustrated in FIG. 22B, the thin layer 73r of the resist pattern 73p is removed.

As illustrated in FIG. 22C, the pattern layer 201 is etched using the resist pattern 73p as a mask. Therefore, a predetermined pattern 203 is formed in the pattern layer 201. In an area vertically overlapping the alignment mark MKt of the substrate 121, the pattern layer 201 has a flat surface.

As illustrated in FIG. 22D, the resist pattern 73p is removed by ashing.

As described above, the template mold 200 of the second embodiment is manufactured.

With the above configuration, the template mold 200 of the second embodiment is configured to once remove the pattern layer 201 by dry etching, wet etching, or the like to form the pattern layer 201 having a new pattern 203, for example, upon reproduction due to wearing out of the pattern layer 201 or upon changing the pattern 203 in the pattern layer 201.

### (Method of Manufacturing Template)

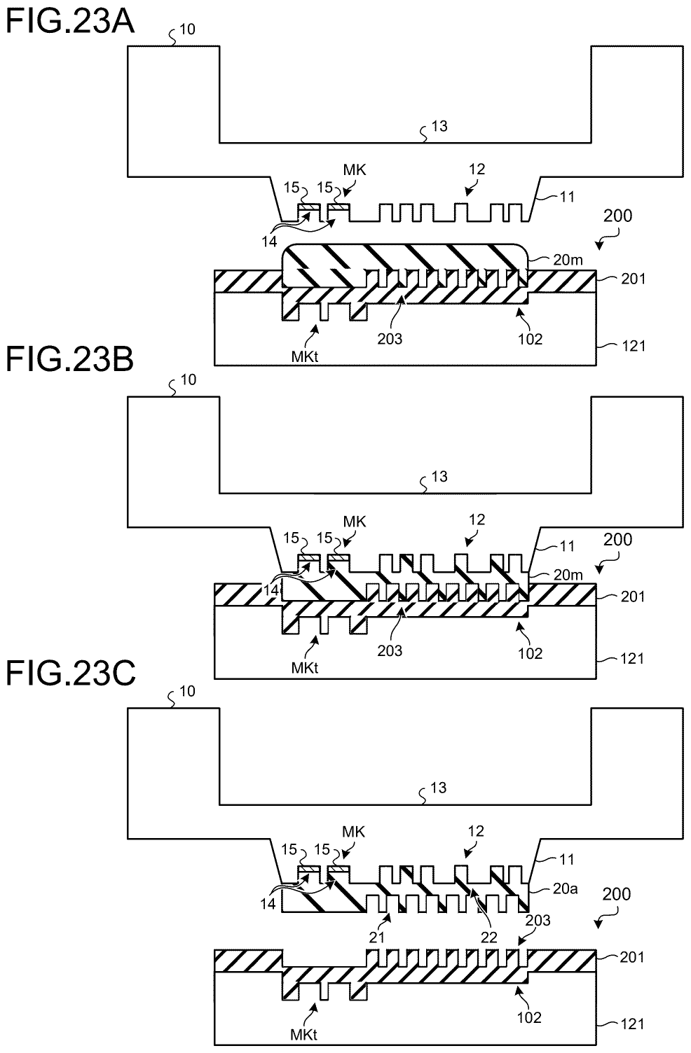

Next, a method of manufacturing a template using the template mold 200 of the second embodiment will be described with reference to FIGS. 23A to 23C. For example, a template corresponding to the template 1 of the first embodiment described above is manufactured from the template mold 200.

FIGS. 23A to 23C are cross-sectional views sequentially illustrating parts of a procedure of a method of manufacturing the template according to the second embodiment.

As illustrated in FIG. 23A, the quartz substrate 10 is prepared as in the method of manufacturing the template 1 of the above first embodiment. In other words, the quartz substrate 10 is provided with the mesa portion 11 and the counterbore 13, and the mesa portion 11 is provided with the anchor pattern 12 and the alignment mark MK. Furthermore, the quartz substrate 10 includes the protective layer 41 and the adhesive layer 51.

The quartz substrate 10 described above is opposed to the template mold 200 in which the resin layer 20m covering the upper surface of the pattern layer 201 is formed. Furthermore, at this time, the alignment mark MK of the quartz substrate 10 and the alignment mark MKt provided on the substrate 121 of the template mold 200 are used to align the quartz substrate 10 and the template mold 200.

As illustrated in FIG. 23B, the mesa portion 11 of the quartz substrate 10 is pressed against the resin layer 20m of the template mold 200 to cure the resin layer 20m by entire heating or application of ultraviolet light or the like.

As illustrated in FIG. 23C, when the quartz substrate 10 is raised, the resin layer 20a thermally cured or photo-cured and bonded to the mesa portion 11 by the adhesive layer 51 is pulled up together with the quartz substrate 10, and released from the template mold 200. The resin layer 20a has a shape obtained by removing the recess 24 from the resin layer 20 included in the template 1 of the above first embodiment.

In other words, the resin layer 20a has the pattern 21 to be transferred to the semiconductor substrate or the like on the surface, and has a flat shape in an area vertically overlapping the alignment mark MK. In this way, in the template manufactured from the template mold 200, there is also an advantage that the shape formed in association with the alignment mark MK is not formed on the surface of the resin layer 20a, that is, a transfer surface to the semiconductor substrate.

Thereafter, the protective layer 61 covering the pattern 21 of the resin layer 20a, the quartz substrate 10, and the like is formed by, for example, the ALD method or the like. However, the protective layer 62 of the above first modification of the first embodiment may be formed on the surface of the resin layer 20a where the pattern 21 is formed by using the silicon-containing resin for the resin layer 20a, and oxidizing silicon-containing resin on the surface of the resin layer 20a or removing components other than silicon on the surface.

As described above, the template of the second embodiment is manufactured.

Note that, it is also possible to manufacture a template corresponding to the template 3 or 4 including two types of resin layers 20 and 30 or resin layers 20 and 30a with the template mold 200 of the second embodiment by the methods of the second and third modifications of the above first embodiment.

### (Review)

The template mold 200 of the second embodiment includes the substrate 121 and the pattern layer 201 arranged above the substrate 121 and having the pattern 203 that is transferred to the resin layer 20a of the template and serves as the pattern 21. Therefore, replacement of the pattern layer 201 facilitates reproducing the template mold 200 or change of the pattern 203. In addition, use of the template mold 200 configured as described above, it is possible to manufacture a template having no shape formed in association with the alignment mark MK on the transfer surface of the resin layer 20a to the semiconductor substrate.

### (Modifications)

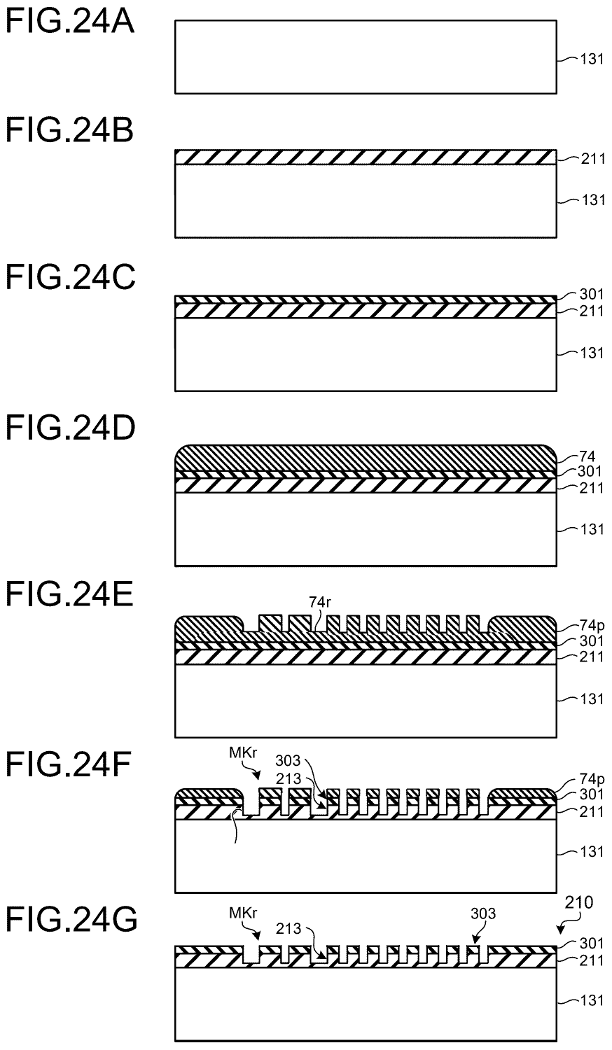

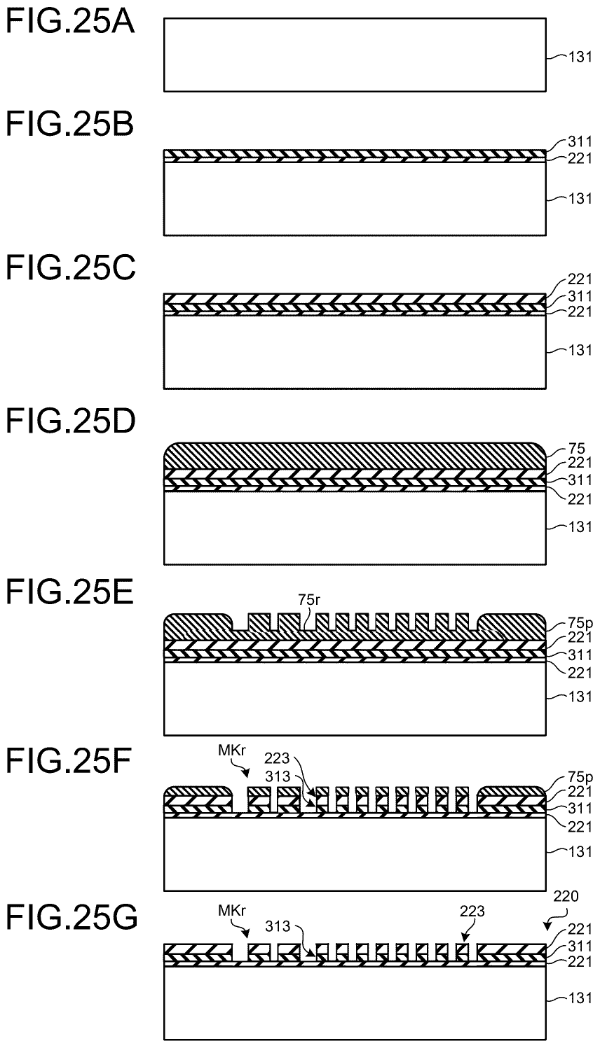

Next, template molds 210 and 220 of a modification of the second embodiment will be described with reference to FIGS. 24A to 25G. In the template molds 210 and 220 of the modification, unlike the second embodiment described above, an alignment mark is formed in a pattern layer such as a TEOS layer, instead of arranging the alignment mark at a base portion of the template molds 210 and 220. Furthermore, in order to improve the visibility of the alignment mark provided in the TEOS layer or the like, two types of pattern layers 211 and 301 or pattern layers 221 and 311 are provided, in the template molds 210 and 220 of the modification.

Note that in the following drawings, the same reference numerals are assigned to configurations similar to those of the above second embodiment, and the description thereof may not be repeated.

FIGS. 24A to 24G are cross-sectional views sequentially illustrating parts of a procedure of a method of manufacturing the template mold 210 according to the modification of the second embodiment.

As illustrated in FIG. 24A, instead of the substrate 121 of the template mold 200 of the above second embodiment, a substrate 131 serving as a base of the template mold 210 of the modification is prepared. The substrate 131 is not provided with the recess, alignment mark, and the like, and the substrate 131 has a substantially flat surface.

As illustrated in FIG. 24B, the pattern layer 211 such as the TEOS layer covering an upper surface of the substrate 131 is formed.

As illustrated in FIG. 24C, the pattern layer 301 covering an upper surface of the pattern layer 211 is formed. The pattern layer 301 is, for example, at least one of an amorphous silicon layer, a silicon nitride layer, or a metal layer, and is made of a material different from that of the pattern layer 211.

As illustrated in FIG. 24D, a resist layer 74 covering an upper surface of the pattern layer 301 is formed. Note that an SOC layer, an SOG layer, or the like may be provided between the resist layer 74 and the pattern layer 301.

As illustrated in FIG. 24E, in addition to the pattern Mp of the master template M3 of the above second embodiment, a master template having a recess for forming an alignment mark in the pattern layers 211 and 301 is pressed against the resist layer 74 of the substrate 131, and the resist layer 74 is cured by applying ultraviolet light, and a resist pattern 74p having a thin layer 74r at the bottom is formed.

As illustrated in FIG. 24F, the thin layer 74r of the resist pattern 74p is removed, and the pattern layers 301 and 211 are etched using the resist pattern 74p as a mask. Therefore, predetermined patterns 303 and 213 are formed in the pattern layers 301 and 211, and an alignment mark MKr obtained by processing the pattern layers 301 and 211 into a protruding shape is formed.

As a result, at an upper end of the pattern 213 in the pattern layer 211 such as a silicon oxide layer, the pattern layer 301 as a heterogeneous layer is arranged with the pattern 303 vertically overlapping the pattern 213 in the pattern layer 211.

As illustrated in FIG. 24G, the resist pattern 74p is removed by ashing.

As described above, the template mold 210 of the modification is manufactured.

Note that the amorphous silicon layer, the silicon nitride layer, the metal layer, or the like can be formed at different positions in the silicon oxide layer.

FIGS. 25A to 25G are cross-sectional views sequentially illustrating parts of a procedure of a method of manufacturing another template mold 220 according to a modification of the second embodiment.

As illustrated in FIG. 25A, instead of the substrate 121 of the template mold 200 of the above second embodiment, the substrate 131 serving as a base of the template mold 220 of the modification is prepared.

As illustrated in FIG. 25B, the pattern layer 221 such as the TEOS layer covering the upper surface of the substrate 131 is formed. However, the formation of the pattern layer 221 is once stopped, and the pattern layer 311 is formed that covers an upper surface of the pattern layer 221 and is at least one of an amorphous silicon layer, a silicon nitride layer, or a metal layer.

As illustrated in FIG. 25C, the pattern layer 211 is continuously formed so as to cover an upper surface of the pattern layer 311.

Accordingly, the pattern layer 311 as the heterogeneous layer is interposed in the pattern layer 221 including, for example, a silicon oxide layer or the like.

As illustrated in FIG. 25D, a resist layer 75 covering the upper surface of the pattern layer 221 above the pattern layer 311 is formed. Note that an SOC layer, an SOG layer, or the like may be provided between the resist layer 75 and the pattern layer 311.

As illustrated in FIG. 25E, in addition to the pattern Mp of the master template M3 of the above second embodiment, a master template having a recess for forming an alignment mark in the pattern layers 211 and 301 is pressed against the resist layer 75 of the substrate 131, and the resist layer 75 is cured by applying ultraviolet light, and a resist pattern 75p having a thin layer 75r at the bottom is formed.

As illustrated in FIG. 25F, the thin layer 75r of the resist pattern 75p is removed, and the pattern layer 221 above the pattern layer 311 and the pattern layer 311 are etched using the resist pattern 75p as a mask. Therefore, predetermined pattern 223 and 313 are formed in the pattern layers 221 and 311, and the alignment mark MKr obtained by processing the pattern layers 221 and 311 is processed into a protruding shape is formed. In addition, the pattern layer 221 below the pattern layer 311 is exposed from the bottom of these patterns 223 and 313.

As a result, at a lower end of the pattern 223 in the pattern layer 221 such as a silicon oxide layer, the pattern layer 311 as a heterogeneous layer is arranged with the pattern 313 vertically overlapped with the pattern 223 of the pattern layer 221.

As illustrated in FIG. 25G, the resist pattern 75p is removed by ashing.

As described above, another template mold 220 of the modification is manufactured.

When a resin layer of a template is formed using a template mold having a pattern layer such as a silicon oxide layer, the silicon oxide layer and the resin layer have a close refractive index, and therefore, visibility of an alignment mark provided in the pattern layer is reduced, and there is a concern that alignment accuracy between the template mold and a quartz substrate of the template may be reduced.

The template mold 210 of the modification includes the pattern layer 211 arranged above the substrate 131 and having the pattern 213 that is transferred to the resin layer 20a and serves as the pattern 21, and the pattern layer 301 arranged at the upper end of the pattern 213 included in the pattern layer 211 and made of a material different from that of the pattern layer 211.

In this way, provision of the pattern layer 301 as the heterogeneous layer at the upper end of the pattern 213 in the pattern layer 211 makes it possible to increase the visibility of the alignment mark MKr provided in the pattern layers 211 and 301. This configuration enables improvement of the alignment accuracy between the template mold 210 and the quartz substrate 10 of the template.

Furthermore, when the pattern layer 211 is etched, the pattern layer 301 at the upper end of the pattern 213 functions as a hard mask layer, and therefore, a dimensional conversion difference between the patterns 213 and 303 formed in the template mold 210 can be reduced. In addition, it is also possible to form the patterns 213 and 303 having a higher aspect ratio as a whole.

The template mold 220 of the modification includes the pattern layer 221 arranged above the substrate 131 and having the pattern 223 that is transferred to the resin layer 20a and serves as the pattern 21, and the pattern layer 311 arranged at the lower end of the pattern 223 included in the pattern layer 221 and made of a material different from that of the pattern layer 221.

Such a configuration enables to increase the visibility of the alignment mark MKr provided in the pattern layers 221 and 311, and improve the alignment accuracy between the template mold 220 and the quartz substrate 10 of the template as well.

Furthermore, when the pattern layer 221 is etched, the pattern layer 311 at the lower end of the pattern 223 functions as a stopper layer, and therefore, variations in the depth of the patterns 223 and 313 formed in the template mold 220 can be suppressed.

### [Supplementary Notes]

Hereinafter, preferred aspects of the present invention will be additionally described.

### (Supplementary Note 1)

According to one aspect of the present invention,
provided is a template reproduction method,
in which
the template includes:
a substrate;
a resin layer that is bonded to the substrate and has a pattern on a first surface opposite to a second surface facing a substrate; and
a first protective layer that covers the surface of the resin layer having the pattern,
the resin layer and the substrate are provided with a recess and a protrusion configured to be fitted to each other on each opposed surface of the resin layer and the substrate, and
the substrate includes:
a mesa portion that protrudes from a third surface of the substrate, the mesa portion having a bonding surface to the resin layer; and
an adhesive layer that is interposed between the mesa portion and the resin layer, and
the method comprising:
removing the adhesive layer from an exposed portion of the adhesive layer to peel off the resin layer.

### (Supplementary Note 2)

In the template reproduction method according to Supplementary Note 1,
newly applying the adhesive layer to the mesa portion from which the resin layer has been peeled off,
newly applying the resin layer to the mesa portion via the adhesive layer, and
newly forming the first protective layer covering the surface of the resin layer having the pattern.

### (Supplementary Note 3)

In the template reproduction method according to Supplementary Note 2,
formation of the first protective layer includes:
depositing the first protective layer on the third surface of the substrate including the resin layer newly bonded, by an atomic layer deposition method; or
oxidizing the surface of the resin layer to a predetermined depth, or removing components other than silicon on the surface of the resin layer, the resin layer being a silicon-containing resin layer.

### (Supplementary Note 4)

In the template reproduction method according to Supplementary Note 1,
the first protective layer covers the surface of the resin layer having the pattern, a side surface of the mesa portion, the one surface of the substrate, and a side surface of the substrate, and
the removal of the adhesive layer includes
removing the first protective layer on the third surface of the substrate to expose the adhesive layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A template comprising:
a substrate; and
a resin layer that is bonded to the substrate and has a pattern on a first surface opposite to a second surface facing a substrate,
wherein the resin layer and the substrate are provided with a recess and a protrusion configured to be fitted to each other on each opposed surface of the resin layer and the substrate.

2. The template according to claim 1, wherein
the recess has a tapered shape narrowing from a bottom surface of the recess toward an open end of the recess, and
the protrusion has a tapered shape widening from a base portion of the protrusion toward an upper end of the protrusion.

3. The template according to claim 1, wherein
the resin layer has at least one selected from the group consisting of
the protrusion fitted into the recess of the substrate, and
the recess into which the protrusion of the substrate is fitted.

4. The template according to claim 1, wherein
the substrate includes:
a mesa portion that protrudes from a third surface of the substrate, the mesa portion having a bonding surface to the resin layer; and
an adhesive layer interposed between the mesa portion and the resin layer.

5. The template according to claim 4, wherein
the adhesive layer covers the bonding surface of the mesa portion, a side surface of the mesa portion, and the third surface of the substrate.

6. The template according to claim 4, further comprising
a first protective layer that covers the surface of the resin layer having the pattern.

7. The template according to claim 6, wherein
the first protective layer covers the surface of the resin layer having the pattern, a side surface of the mesa portion, the third surface of the substrate, and a side surface of the substrate.

8. The template according to claim 6, further comprising
a second protective layer that is interposed between the mesa portion and the adhesive layer.

9. The template according to claim 8, wherein
the second protective layer covers the bonding surface of the mesa portion, a side surface of the mesa portion, the third surface of the substrate, and a side surface of the substrate.

10. The template according to claim 8, wherein
the adhesive layer is an SOC layer,
the first protective layer is a silicon oxide layer, and
the second protective layer is at least one selected from the group consisting of a titanium oxide layer, an aluminum oxide layer, and a silicon oxide layer.

11. The template according to claim 1, wherein
the resin layer includes:
a first resin layer that has the pattern; and
a second resin layer that has a bonding surface to the substrate, the second resin layer being interposed between the first resin layer and the substrate and having a gas permeability higher than the first resin layer,
the second resin layer includes
at least one selected from the group consisting of the recess and the protrusion, on the bonding surface, and
the substrate includes, on a bonding surface to the second resin layer, at least one selected from the group consisting of
the protrusion fitted into the recess of the second resin layer, and
the recess into which the protrusion of the second resin layer is fitted.

12. The template according to claim 1, wherein
the resin layer includes:
a first resin layer that has the pattern; and
a second resin layer that has a bonding surface to the substrate, the second resin layer being interposed between the first resin layer and the substrate and having a gas permeability higher than the first resin layer,
the first resin layer includes
at least one selected from the group consisting of the recess and the protrusion, on a surface facing the substrate via the second resin layer, and
the second resin layer includes, on a surface facing the first resin layer, at least one selected from the group consisting of
the protrusion fitted into the recess of the first resin layer, and
the recess into which the protrusion of the first resin layer is fitted.

13. The template according to claim 11, wherein
the first resin layer is at least one selected from the group consisting of a silicon-containing resin layer, an acrylic resin layer, and a urethane resin layer, and
the second resin layer is at least one selected from the group consisting of an SOC layer and a porous resin.

14. The template according to claim 1, further comprising
an alignment mark that is arranged at a position not overlapping the pattern in upper and lower directions, and has a metal layer between the substrate and the resin layer.

15. The template according to claim 11, further comprising
an alignment mark that is arranged at a position not overlapping the pattern in upper and lower directions, and has a metal layer between the first resin layer and the second resin layer.

16. A template comprising:
a substrate;
an alignment mark that is provided on the substrate and has a metal layer;
a first protective layer that covers the substrate and the alignment mark;
a resin layer that is bonded to the first protective layer covering the substrate with an adhesive layer interposed, the resin layer having a pattern on an opposite surface to a bonding surface to the first protective layer; and
a second protective layer that covers the resin layer.

17. A method of manufacturing a template, comprising
preparing a template mold includes:
a template mold substrate;
a first layer that is arranged above the template mold substrate, and has a pattern; and
a second layer that is arranged at an upper end or a lower end of the pattern included in the first layer, and has a material different from that of the first layer; and
bonding a template substrate to the template mold.

18. The method of manufacturing a template according to claim 17, wherein
the first layer is a silicon oxide layer, and
the second layer is at least one selected from the group consisting of an amorphous silicon layer, a silicon nitride layer, and a metal layer.
